(19) United States
(12) Patent Application Publication
(10) Pub. No.: US 2007/0048637 A1
(43) Pub. Date: Mar. 1, 2007

(54) Arylamine polymer and organic thin film transistor

(76) Inventors: Takashi Okada, Yokohama-shi (JP); Masaomi Sasaki, Susono-shi (JP); Masafumi Torii, Yokohama-shi (JP); Shinichi Kawamura, Yokohama-shi (JP); Toshiya Sagisaka, Yokohama-shi (JP); Yoshikazu Akiyama, Yokohama-shi (JP); Takumi Yamaga, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/512,125

(22) Filed: Aug. 30, 2006

(30) Foreign Application Priority Data
Aug. 30, 2005 (JP) 2005-249285
Mar. 9, 2006 (JP) 2006-064169

(51) Int. Cl. H01L 29/08

(52) U.S. Cl. 430/58.75; 257/40

(57) ABSTRACT

An arylamine polymer containing a repeating unit represented by the following chemical structure (I):

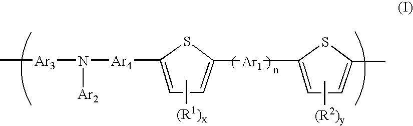

In the chemical structure, Ar₁, Ar₃, and Ar₄ independently represent a substituted or non-substituted divalent aromatic hydrocarbon group, Ar₂ represents a substituted or non-substituted univalent aromatic hydrocarbon group, R¹ and R² independently represent a hydrogen atom, a substituted or non-substituted alkyl group, a substituted or non-substituted alkoxy group or a substituted or non-substituted alkylthio group, x and y independently represent an integer of from 0 to 2, and n represents 0 or 1.

### BACKGROUND OF THE INVENTION

1. Field of the Invention

The present invention relates to an arylamine polymer, and an organic transistor having an organic semiconductor layer containing the arylamine polymer.

2. Discussion of the Background

Various kinds of functional elements such as photoelectric conversion elements, thin layer transistor elements and luminous elements are proposed based on luminous characteristics and carrier transport characteristics of organic materials. Elements using such organic materials are expected to fully utilize the merits thereof, for example, light weight, flexibility, inexpensiveness and low manufacturing cost.

Among these functional elements, various kinds of low molecular weight materials and polymers are proposed for photoelectric conversion elements, especially as materials for solar batteries and carrier transport materials for use in electrophotography. Further efficiency is demanded for the low molecular weight material, and high speed performance and durability are demanded for the polymers.

In addition, various kinds of low molecular weight materials and polymers are proposed as materials for luminous elements. For example, the efficiency of low molecular weight materials is improved by adopting a wide variety of layered structures. The durability is improved by desirably controlling the doping method.

However, in the case of such a low molecular weight material, i.e., a collective of low molecular weight materials, it is reported that the status of the layer changes when the low molecular weight material is used for an extended period of time. That is, such a low molecular weight material has an essential problem of the stability of a layer over time.

On the other hand, with regard to the polymer materials, intensive studies have been made on poly-p-phenylenevinylene (PPV) series, poly-thiophene, etc.

However, high performance luminous elements have not been obtained because of unsolved drawbacks such as difficulty in improving purity of the material and low fluorescence quantum yield.

In spite of these drawbacks, further improvements have been made on the polymer materials. This is because, since polymer materials are stable in a glass state, an excellent luminous element can be manufactured when the fluorescence quantum yield is improved.

Polymer materials having an arylamine unit as a repeating unit are specified as such polymer materials, for example in WO99/20675, WO97/09394, WO03/035714, published unexamined Japanese patent applications Nos. H10-310635 and H08-157575 and Synth. Met., 84, 269 (1997).

In addition, with regard to organic transistor elements, various kinds of low molecular weight materials and polymer materials are proposed. For example, pentacene, phthalocyanine, fullerene, anthradithiophene, thiophene oligomer, and bisdithienothiophene are specified as the low molecular weight materials, and polythiophene, polythienylenevinylene and polyarylamine are specified as the polymer materials.

The polymer materials specified in the documents are greatly improved for the mobility, which is an important characteristic for materials for organic electronics. However, polymer materials having a higher mobility are demanded in terms of application for organic electronics, especially organic field effect transistors (FET).

Further, to apply organic materials having characteristics of low cost manufacturing, sufficient flexibility and strength, light weight and possible increase in size to various kinds of functional elements (photoelectric conversion elements, transistor elements and luminous elements) and fully utilize the characteristics thereof, it is desired that the organic materials are sufficiently soluble in an organic solvent. However, pi-conjugated polymers having a characteristic structure of elongated conjugations are inflexible in general. This inflexible structure is a cause of lowering the solubility of such pi-conjugated polymers.

The polymer materials specified in the documents mentioned above tend to have a difficulty in solubility thereof. Wide-ranging molecular designs have been attempted to solve this drawback relating to the solubility.

The present inventors previously found that polymer materials having an arylamine unit (including ethylene) as a repeating unit having a pi-conjugated linkage as its main chain have an excellent luminous characteristic and are useful for an organic electroluminescence (EL) element having excellent durability and an active layer of an organic transistor. However, in consideration of application of such a polymer material to organic electronic elements, especially organic field-effect transistor (FET) elements, the mobility is desired to be further improved.

In addition, the study and development of organic thin film (TFT) transistors using organic semiconductor materials has been active in recent years. Thin layers of organic semiconductor materials can be easily formed by an easy method such as a printing method and a spin coating method using a wet process. Thin layers of organic semiconductor materials also have an advantage over a thin layer formed of inorganic semiconductor materials in that the temperature of the manufacturing process can be lowered. Thereby, it is possible to form a thin layer on a plastic substrate generally having a low thermal durability so that electronic devices such as displays can be reduced in weight and cost. Further, the latitude of designing is broad because of the flexibility of such a plastic substrate.

JOP H05-55568 describes acene based materials, e.g., pentacene, as an organic semiconductor material. The organic transistor using pentacene as an organic semiconductor layer is reported to have a relatively high mobility. However, these acene based materials have an extremely low solubility in a typical solvent. Therefore, when such an acene based material is used to form a thin organic semiconductor layer of an organic transistor, a vacuum deposition method is desired to be used. Therefore, one of the merits of organic semiconductor materials, i.e., easy manufacturing methods such as coating and printing, is not fully utilized.

In addition, as organic polymer semiconductor materials, Appl. Phys. Lett., 69(26), 4108 (1996) and Science, 290, 2123 (2000) describe poly(3-alkylthiophen) and a copolymer of dialkylfulolene and bithiophene, respectively. Since these organic semiconductor materials have a low but sufficient solubility by introduction of alkyl groups, a thin layer thereof can be formed not by a vacuum deposition process but by coating and printing. These polymeric organic semiconductor materials have a high mobility in a state in which molecules are arranged in order. However, the arrangement state of the molecules depends on the kinds of solvents and coating methods. As a result, this leads to a problem of variation of the characteristics of transistors and deficiency of reproducibility of the characteristics.

### SUMMARY OF THE INVENTION

Because of these reasons, the present inventors recognize that a need exists for an arylamine polymer having an excellent mobility characteristic and which can be inexpensively manufactured and used as a material for use in organic electronic materials such as luminous elements, FET elements, and photoelectric conversion elements, and for an organic thin film transistor which can be manufactured by an easy method such as coating and printing and has a good reproducibility. The mobility characteristic represented in the present invention is a mobility characteristic of a charge based on positive hole transfer.

Accordingly, an object of the present invention is to provide an arylamine polymer having an excellent mobility characteristic and which can be inexpensively manufactured and used as a material for use in organic electronic materials and an organic thin film transistor which can be manufactured by an easy method such as coating and printing and has a good reproducibility.

Briefly these objects and other objects of the present invention as hereinafter described will become more readily apparent and can be attained, either individually or in combination thereof, by an arylamine polymer containing a repeating unit represented by the following chemical structure (I), 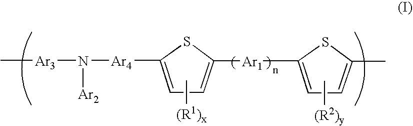
In the chemical structure (I), Ar₁, Ar₃, and Ar₄ each, independently, represent a substituted or non-substituted divalent aromatic hydrocarbon group, Ar₂ represents a substituted or non-substituted univalent aromatic hydrocarbon group, R¹ and R² each, independently, represent a hydrogen atom, a substituted or non-substituted alkyl group, a substituted or non-substituted alkoxy group or a substituted or non-substituted alkylthio group, x and y each, independently, represent an integer of from 0 to 2, and n represents 0 or 1;

and the use of the arylamine polymer to provide an organic semiconductor layer for an organic thin film transistor.

These and other objects, features and advantages of the present invention will become apparent upon consideration of the following description of the preferred embodiments of the present invention taken in conjunction with the accompanying drawings.

### BRIEF DESCRIPTION OF THE DRAWINGS

Various other objects, features and attendant advantages of the present invention will be more fully appreciated as the same becomes better understood from the detailed description when considered in connection with the accompanying drawings in which like reference characters designate like corresponding parts throughout and wherein:

FIGS. 1A to 1D are schematic diagrams illustrating an organic thin film transistor related to the present invention;

FIG. 2 is a diagram illustrating an infrared absorption spectrum of an example polymer of the present invention;

FIG. 3 is a diagram illustrating an infrared absorption spectrum of another example polymer of the present invention;

FIG. 4 is a diagram illustrating an infrared absorption spectrum of an example polymer of the present invention;

FIG. 5 is a diagram illustrating an infrared absorption spectrum of another example polymer of the present invention;

FIG. 6 is a diagram illustrating an infrared absorption spectrum of an example polymer of the present invention;

FIG. 7 is a diagram illustrating an infrared absorption spectrum of another example polymer of the present invention;

FIG. 8 is a diagram illustrating an infrared absorption spectrum of an example polymer of the present invention;

FIG. 9 is a diagram illustrating an infrared absorption spectrum of another example polymer of the present invention;

FIG. 10 is a diagram illustrating the measuring results of transistor characteristics of a manufactured example of the present invention;

FIG. 11 is a diagram illustrating the measuring results of transistor characteristics of another manufactured example of the present invention;

FIG. 12 is a diagram illustrating the measuring results of transistor characteristics of another manufactured example of the present invention;

FIG. 13 is a diagram illustrating the measuring results of transistor characteristics of another manufactured example of the present invention;

FIG. 14 is a diagram illustrating the measuring results of transistor characteristics of another manufactured example of the present invention;

FIG. 15 is a diagram illustrating the measuring results of transistor characteristics of another manufactured example of the present invention; and

FIG. 16 is a diagram illustrating the measuring results of transistor characteristics of another manufactured example of the present invention.

### DETAILED DESCRIPTION OF THE INVENTION

The present invention is described in detail below with reference to drawings.

The arylamine polymers of the present invention are polymeric materials including the repeating unit represented by the following chemical structures (I) to (III):

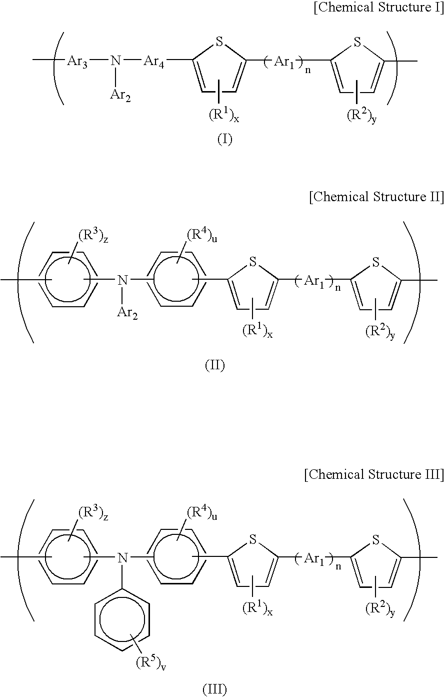

Thus, the present invention relates to an arylamine polymer containing a repeating unit represented by the following chemical structure (I),

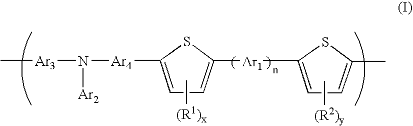

In the chemical structure (I), Ar₁, Ar₃, and Ar₄ each, independently, represent a substituted or non-substituted divalent aromatic hydrocarbon group, Ar₂ represents a substituted or non-substituted univalent aromatic hydrocarbon group, R¹ and R² each, independently, represent a hydrogen atom, a substituted or non-substituted alkyl group, a substituted or non-substituted alkoxy group or a substituted or non-substituted alkylthio group, x and y each, independently, represent an integer of from 0 to 2, and n represents 0 or 1.

It is preferred that, in the arylamine mentioned above, the repeating unit is represented by the following chemical structure (II),

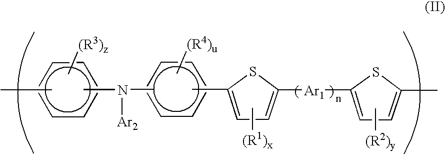

wherein Ar₁ represents a substituted or non-substituted divalent aromatic hydrocarbon group, Ar₂ represents a substituted or non-substituted univalent aromatic hydrocarbon group, R¹, R², R³ and R⁴ independently represent a hydrogen atom, a substituted or non-substituted alkyl group, a substituted or non-substituted alkoxy group, or a substituted or non-substituted alkylthio group, x and y independently represent an integer of from 0 to 2, z and u independently represent an integer of from 0 to 4, and n represents 0 or 1.

It is still further preferred that, in the arylamine mentioned above, the repeating unit is represented by the following chemical structure (III), 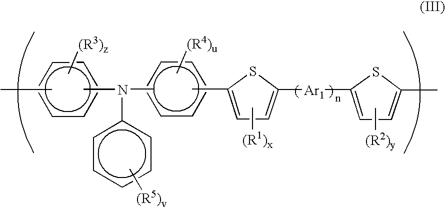
wherein Ar₁ represents a substituted or non-substituted divalent aromatic hydrocarbon group, R¹, R², R³, R⁴, and R⁵ independently represent a hydrogen atom, a substituted or non-substituted alkyl group, a substituted or non-substituted alkoxy group, or a substituted or non-substituted alkylthio group, x and y independently represent an integer of from 0 to 2, z and u independently represent an integer of from 0 to 4, v represents an integer of from 0 to 5 and n represents 0 or 1.

As another aspect of the present invention, an organic thin film transistor is provided which contains an organic semiconductor layer containing the arylamine mentioned above.

It is preferred that the organic thin film transistor further includes a structure including a pair of electrodes for applying a current through the organic semiconductor layer and a third electrode.

It is still further preferred that, in the organic thin film transistor, the third electrode and the structure are provided with an insulating layer therebetween.

The arylamine polymers of the present invention can be used as charge transfer polymers for organic transistors, polymers for use in organic thin film electroluminescence elements or materials for use inorganic electronics for electrophotographic image bearing member materials.

Below are descriptions of a method of manufacturing the arylamines of the present invention.

For example, a cross coupling reaction (Suzuki Coupling) in which a halogenated aryl compound and a boron aryl compound are used and another cross coupling reaction (Stille Coupling) in which a halogen aryl compound and a tin aryl compound are used can be used. Known manufacturing methods can be used to manufacture the arylamine polymer.

A method of manufacturing the arylamine polymer of the present invention using Suzuki Coupling is described. The arylamine polymer of the present invention is generally obtained by heating a solution in which a boronic acid compound or an ester of a boronic acid and a halogen compound are stoichiometrically equally present under the presence of a palladium catalyst and a base to conduct a polymerization reaction. In addition, a random copolymer can be obtained by adding multiple kinds of boronic acid compounds or halogen compounds in the reaction process. Thereby, it is possible to adjust characteristics of the arylamine polymer.

Halogen atoms contained in the halogenated aryl compound are preferably iodine atom or bromine atom in terms of reactivity.

An aryl boronic acid or an ester thereof is used as the boron aryl compound. An ester of an aryl boronic acid is preferred since the ester of an aryl boronic acid does not produce a cyclic anhydride (boroxine) formed of a trimer, which is produced when an aryl boronic acid is used. In addition, when an ester of an aryl boronic acid is used, the synthesized compound has a high crystalline property and purification thereof is easy.

Specific examples of synthesizing an ester of aryl boronic acid are as follows:
(i) Heat an aryl boronic acid and an alkane diol in an organic anhydrate solvent;
(ii) Metallize a halogen portion of a halogenated aryl compound and add an ester of an alkoxyboron thereto;
(iii) Prepare a Grignard reagent of an aryl halogen and add an ester of an alkoxyboron thereto; and
(iv) Heat a halogenated aryl compound and bis(pinacolate) diboron or bis(neopentyl glycolate)diboron under the presence of a palladium catalyst.

Specific examples of the palladium catalysts include, but are not limited to, Pd(PPh₃)₄, PdCl₂ (PPh₃)₂, Pd(OAC)₂, PdCl₂ and a catalyst in which triphenyl phosphine is added to palladium-carbon as a ligand. Pd(PPh₃)₄ is most commonly used.

A base is required for this reaction. Good results are obtained when a relatively weak base such as Na₂CO₃, NaHCO₃ and K₂CO₃ is used. A strong base such as Ba(OH)₂ and K₃PO₄ is effective for addressing problems such as steric hindrance. Other specific examples thereof include caustic soda, caustic potash and metal alkoxides such as potassium t-butoxide, sodium t-butoxide, lithium t-butoxide, potassium 2-methyl-2-butoxide, sodium 2-methyl-2-butoxide, sodium methoxide, sodium ethoxide, potassium ethoxide and potassium methoxide.

In addition, to smoothly conduct the reaction, it is possible to use a phase transfer catalyst. For example, tetraalkyl halogenated ammonium, tetraalkyl ammonium hydrogen sulfate and tetraalkylammonium hydroxide can be used. Preferred specific examples thereof include, but are not limited to, tetra-n-butyl halogenated ammonium, benzyl triethyl halogenated ammonium and tricaprylylmethyl ammonium chlorinate.

Specific examples of the reaction solvents include, but are not limited to, alcohols and ethers such as methanol, ethanol, isopropanol, butanol, 2-methoxyethanol, 1,2-dimethoxyethane, bis(2-methoxyethyl) ether; cyclic ethers such as dioxane and tetrahydrofuran; benzene, toluene, xylene, dimethylsulfoxide, N,N-dimethylformamide, N-methylpyrrolidone, and 1,3-dimethyl-2-imidazolidinone.

The reaction temperature of the polymerization mentioned above is determined depending on the reactivity of the monomer and/or reaction solvent used but is preferred to be set at a temperature not higher than the boiling point of the solvent.

The reaction time in the polymerization reaction mentioned above can be determined depending on the reactivity of a monomer used or the molecular weight of a desired polymer and preferably ranges from 2 to 50 hours and more preferably from 5 to 24 hours.

It is also possible to add a molecular weight controlling agent to control the molecular weight in the polymerization process or an endcapping agent as an endmodifying group for a polymer to have its end. These agents can be added in the reaction process or at when the reaction starts. Therefore, a group based on an endcapping agent can be bonded at the end of the polymer of the present invention.

A compound having one pharmacophore such as phenyl boronic acid, bromobenzene or iodobenzene, can be used as the molecular weight controlling agent or the endcapping agent.

The polymer of the present invention preferably has an average molecular weight of from 1,000 to 1,000,000 in polystyrene conversion number and more preferably, from 2,000 to 500,000. A molecular weight that is too small may cause practical problems such as cracking, i.e., deterioration the layer forming property. A molecular weight that is too large may also cause practical problems such as deterioration of solubility in a typical organic solvent, resulting in an increase in the viscosity of the solvent, which leads to difficulty in application of the solvent.

In addition, it is also possible to add a small amount of a branching agent during polymerization to improve the mechanical characteristics of the arylamine polymer. Compounds having three of the same or different pharmacophores can be used as the branching agent and these can be used alone or in combination.

The thus obtained arylamine polymer of the present invention is used after removing materials used for polymerization, such as the base, non-reactive monomers and the endcapping agents, and impurities, such as inorganic salts generated during the polymerization. In this purification process, known methods such as reprecipitation, extraction, soxhlet extraction, extracorporeal ultrafiltration (ECUM) and dialysis can be used.

Specific examples of the thus obtained polymers having the repeating units represented by the chemical structures (I) to (III) are as follows.

A univalent substituted or non-substituted aromatic hydrocarbon group Ar₂ in the chemical structure (I) can be a monocyclic or a polycyclic group (condensation polycyclic group, non-condensation polycyclic group). Specific examples thereof include, but are not limited to, phenyl group, naphthyl group, vinylene group, fluorenyl group, azulenyl group, anthryl group, triphenylenyl group, glycenyl group, biphenyl group and terphenyl group. Divalent groups of the substituted or non-substituted aromatic hydrocarbon groups mentioned above can be used as the substituted or non-substituted divalent aromatic hydrocarbon groups Ar₁, Ar₃ and Ar₄ in the chemical structure (I).

These groups (Ar₁, Ar₂, Ar₃ and Ar₄) having a cyclic structure can have various kinds of substitutional groups as follows:
(1) halogen atoms, trifluoromethyl group, cyano group, nitro group;
(2) straight chained or branch chained alkyl groups or alkoxy groups having 1 to 25 carbon atoms; these can be further substituted by halogen atom, cyano group, phenyl group, hydroxyl group, carboxyl group, alkoxy group and alkylthio group;
(3) aryloxy groups (having phenyl group and naphthyl group as aryl group. These can contain a halogen atom as a substitutional group and also straight chained or branch chained alkyl groups, alkoxy groups and alkylthio groups having 1 to 25 carbon atoms. Specific examples thereof include, but are not limited to, phenoxy group, 1-naphthyloxy group, 2-naphthyloxy group, 4-methylphenoxy group, 4-methoxyphenoxy group, 4-chlorophenoxy group, and 6-methyl-2-naphthyloxy group);
(4) alkylthio groups or arylthio groups (Specific examples thereof include, but are not limited to, methylthio group, ethylthio group, phenylthio group, p-methylphenylthio group.);
(5) alkyl substituted amino groups (Specific examples thereof include, but are not limited to, diethyl amino group, N-methyl-N-phenyl amino group, N,N-diphenyl amino group, N,N-di(p-tolyl) amino group, dibenzyl amino group, pipelidino group, morpholino group, and julolidyl group.); and
(6) acyl groups (Specific examples thereof include, but are not limited to, acetyl group, propionyl group, butyryl group, malonyl group and benzoyl group).

The arylamine polymers having the repeating units represented by the chemical structures (I) to (III) can have a halogen atom, a substituted or non-substituted alkyl group, or a substituted or non-substituted alkoxy group on their aromatic rings as substitutional groups. In terms of improvement of the solubility of the arylamine polymers in a solvent, it is preferred to have a substituted or non-substituted alkyl group, a substituted or non-substituted alkoxy group or a substituted or non-substituted alkylthio group.

When the number of carbon atoms of these substitutional groups increases, the solubility of the arylamine polymers increases. However, the charge transport property thereof deteriorates. Therefore, it is preferred to select substitutional groups which can impart desired characteristics to the arylamine polymer in a range in which the solubility does not deteriorate. Preferred specific examples of such suitable substitutional groups include, but are not limited to, alkyl group, alkoxy group or alkylthio group having 1 to 25 carbon atoms. The same or different substituional groups can be independently introduced. In addition, these alkyl groups, alkoxy groups and alkylthio groups can further contain halogen atoms, cyano groups, aryl groups, hydroxyl groups, carboxyl groups, and aryl groups substituted by straight chained, branch chained or cyclic alkyl groups, alkoxy groups or alkylthio groups having 1 to 12 carbon atoms.

Specific examples of the alkyl groups include, but are not limited to, methyl group, ethyl group, n-propyl group, i-propyl group, t-butyl group, s-butyl group, n-butyl group, i-butyl group, pentyl group, hexyl group, heptyl group, octyl group, nonyl group, decyl group, 3,7-dimethyloctyl group, 2-ethylhexyl group, trifluoromethyl group, 2-cyanoethyl group, benzyl group, 4-chlorobenzyl group, 4-methyl benzyl group, cyclopentyl group and cyclohexyl group. Specific examples of the alkoxy groups and the alkylthio groups include, but are not limited to, groups in which an oxygen atom or a sulfur atom is introduced into the linking position of the alkyl groups mentioned above, respectively. That is, these are: methoxyl group, ethoxyl group, n-propoxyl group, i-propoxyl group, t-butoxyl group, s-butoxyl group, n-butoxyl group, i-butoxyl group, pentoxyl group, hexoxyl group, heptoxyl group, octoxyl group, nonoxyl group, decoxyl group, 3,7-dimethyloctoxyl group, 2-ethylhexoxyl group, trifluoromethoxyl group, 2-cyanoethoxyl group, benzoxyl group, 4-chlorobenzoxyl group, 4-methyl benzoxyl group, cyclopentoxyl group and cyclohexoxyl group as alkoxy group; and methylthio group, ethylthio group, n-propylthio group, i-propylthio group, t-butylthio group, s-butylthio group, n-butylthio group, i-butylthio group, pentylthio group, hexylthio group, heptylthio group, octylthio group, nonylthio group, decylthio group, 3,7-dimethyloctylthio group, 2-ethylhexylthio group, trifluoromethylthio group, 2-cyanoethylthio group, benzylthio group, 4-chlorobenzylthio group, 4-methyl benzylthio group, cyclopentylthio group and cyclohexylthio group as the alkylthio group.

Next, the organic thin film transistor of the present invention is described.

Transistor Structure

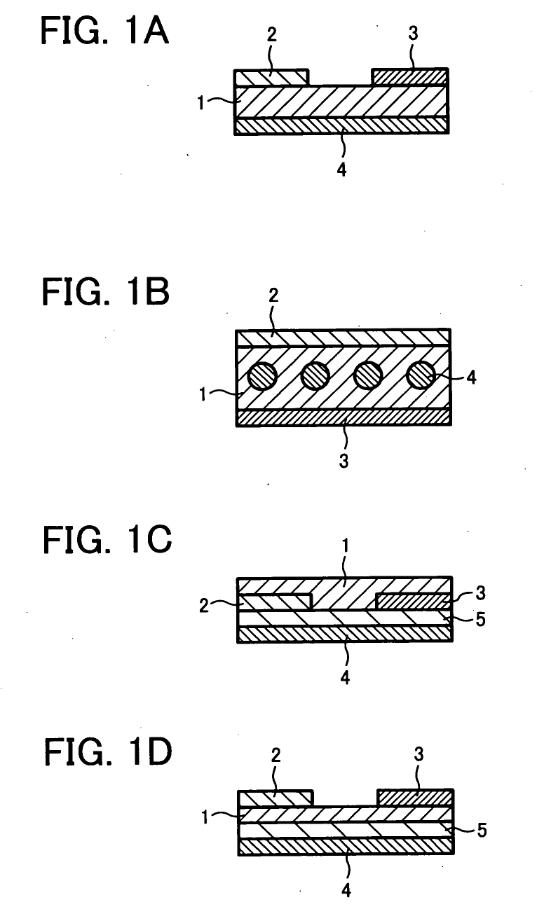

FIGS. 1A to 1D are diagrams illustrating schematic structures of embodiments of the organic thin film transistor of the present invention. An organic semiconductor layer 1 of the organic thin film transistor of the present invention contains the arylamine polymer having one of the repeating units illustrated in the chemical structures (I) to (III). The organic transistor of the present invention includes a source electrode 2, a drain electrode 3 and a gate electrode 4, all of which are spatially separated from each other. As illustrated in FIGS. 1C and 1D, an insulating layer 5 can be provided between the gate electrode 4 and the organic semiconductor layer 1. In the organic thin film transistor, the current flowing in the organic semiconductor layer 1 between the source electrode 2 and the drain electrode 3 is controlled by the voltage applied to the gate electrode 4.

The organic thin film transistor of the present invention can be provided on a substrate. For example, commonly-used substrates such as glass, silicon and plastic can be used. In addition, when an electroconductive substrate is used, the electroconductive substrate itself can function as a gate electrode. Further, a gate electrode can be accumulated on a substrate. Among these substrates, a plastic sheet is preferred in consideration of characteristics such as, for example, flexibility, reduction in weight, inexpensive cost and anti-shocking, desired for a device to which the organic transistor of the present invention is applied.

Specific examples of such plastic sheets include, but are not limited to, films formed of polyethylene terephthalate, polyethylene naphthalate, polyether sulfone, polyether imides, polyether etherketones polyphenyl sulfides, polyarylates, polyimides, polycarbonates, cellulose triacetate, cellulose acetate propionate, etc.

Coating Method: Organic Semiconductor Layer 1

A solution in which the arylamine polymers mentioned above of the present invention is dissolved in a solvent, for example dichloromethane, tetrahydrofuran, chloroform, toluene, dichlorobenzene or xylene, can be coated on the substrate to form a thin layer, i.e., the organic semiconductor layer 1.

Specific examples of the methods of coating the organic semiconductor layer 1 include, but are not limited to, a spray coating method, a spin coating method, a blade coating method, a dip coating method, a casting method, a roll coating method, a bar coating method, a dye coating method, an ink jet method and a dispense method. A good combination is suitably selected among the methods mentioned above of forming a layer and the solvents mentioned above depending on the materials.

The thin film formed by these coating methods has excellent strength, toughness and durability and is free from cracking. Such a thin film is suitable for organic electronics such as photoelectric conversion elements, Field effect transistor (FET) elements and luminescent elements.

In the organic thin film transistor of the present invention, there is no specific limit to the layer thickness of the organic semiconductor layer 1. The layer thickness is set to be in a range in which a uniform layer (i.e., there is no gap and/or hole having an adverse effect on the carrier transport property of the organic semiconductor layer 1) can be formed. The layer thickness of the organic semiconductor layer 1 is typically not greater than 1 μm and preferably from 5 to 200 nm.

Insulating Layer

The insulating layer 5 for use in the organic transistor of the present invention can be formed of various kinds of insulating materials. Specific examples thereof include, but are not limited to, inorganic insulating materials such as silica, silicon nitride, aluminum oxide, aluminum nitride, titanium oxide, tantalum oxide, tin oxide, vanadium oxide, barium strontium titanate, zirconium oxidized barium titanate, zirconic acid lead titanate, lead lanthanum titanate, strontium titanate, barium titanate, barium magnesium fluoride, bismuth niobium acid tantalate, and trioxide yttrium. In addition, polymers such as polyimide, polyvinylalcohol, polyvinylphenol, polyester, polyethylene, polyphenylene sulfide, non-substituted or halogen atom substituted polyparaxylylene, polyacrylonitrile and cyanoethyl pullulan can be also used. These can be used alone or in combination. There is no specific limit to the selection of the insulating materials but it is preferred to select an insulating material having a high dielectric constant and a low electroconductivity.

Specific examples of the methods of manufacturing the insulating layer using the materials mentioned above include, but are not limited to, dry deposition processes such as a chemical vacuum deposition (CVD) method, a plasma CVD method and a plasma polymerization method, and wet coating processes such as a spray coating method, a spin coating method, a dip coating method, an inkjet method, a casting method, a blade coating method and a bar coating method.

Interface Between Organic Semiconductor and Insulating Layer, e.g., Hexamethyldisilazane (HMDS)

In the organic thin film transistor of the present invention, an organic thin layer can be provided between the insulating layer and the organic semiconductor layer to improve the adhesiveness thereof, decrease the gate voltage and reduce the leak current. There is no specific limit to the organic thin layer as long as the organic thin layer does not have a chemical effect on the organic semiconductor layer. For example, an organic molecular film and a polymer thin layer can be used.

As the organic molecular film, coupling agents such as octadecyl trichlorosilane and hexamethylene disilazane can be used. In addition, in the case of the polymer thin layer, the polymer insulating materials mentioned above can be used. These can function as a kind of an insulating layer. This organic thin layer can be subject to an anisotropic treatment by rubbing.

Electrode

There is no specific limit to the gate electrode, the source electrode and the drain electrode for use in the organic thin film transistor of the present invention as long as these electrodes are electroconductive materials. Specific examples thereof include, but are not limited to, platinum, gold, silver, nickel, chromium, copper, iron, tin, antimony, lead, tantalum, indium, aluminum, zinc, magnesium, alloys thereof, electroconductive metal oxides such as indium/tin oxides, organic and inorganic semiconductors in which electroconductivity is improved by doping, etc., such as complexes of silicon single crystal, polysilicon, amorphous silicon, germanium, graphite, polyacetylene, polyparaphenylene, polythiophene, polypyrrole, polyaniline, polythienylene vinylene, polyparaphenylene vinylene, and complex of polyethylene dioxythiophene and polystyrene sulfonic acid.

Among the electroconductive materials mentioned above, materials having a low electroconductivity at the contact phase with the semiconductor layer are preferred for the source electrode.

Specific examples of forming an electrode include, but are not limited to: a method in which a known method such as a photolithographic method and liftoff technology is used to form an electrode from an electroconductive thin layer formed of the material mentioned above by a method such as deposition and sputtering; and a method in which an electrode is formed by etching a resist on a metal foil of, for example, aluminum and copper, by thermal transfer, ink jet, etc. In addition, it is possible to form an electrode by patterning a solution or liquid dispersion of an electroconductive polymer or a liquid dispersion of electroconductive particulates by direct ink jet. Lithography and laser application can be used to form an electrode from a coated layer. It is also possible to use a method in which ink, electroconductive paste, etc. containing electroconductive polymers and/or electroconductive particulates are patterned by a printing method such as intaglio plating, anastatic printing, planographic printing and screen printing.

Extraction Electrode and Protective Layer

The organic thin film transistor of the present invention can have an extraction electrode from each electrode if desired.

The organic thin film transistor of the present invention can be stably operated in the atmosphere. If desired, a protective layer can be provided in terms of protection from mechanical destruction and moisture and/or gas and convenience for integration of a device.

Applied Device

The organic thin film transistor of the present invention can be utilized as elements for driving image display elements such as liquid crystal, organic electroluminescence and electrophoretic migration. When such elements are integrated, it is possible to manufacture a display referred to as “electronic paper”. It is also possible to use ICs in which the organic thin film transistors are integrated as a device such as IC tags.

Having generally described preferred embodiments of this invention, further understanding can be obtained by reference to certain specific examples which are provided herein for the purpose of illustration only and are not intended to be limiting. In the descriptions in the following examples, the numbers represent weight ratios in parts, unless otherwise specified.

### EXAMPLES

The present invention is described with reference to Examples but not limited thereto.

Below are synthetic examples of polymers for use in the present invention.

### Example 1

Synthesis of Polymer 1

Polymer 1 is prepared by polymerization under the following conditions along with the following reaction process 1.

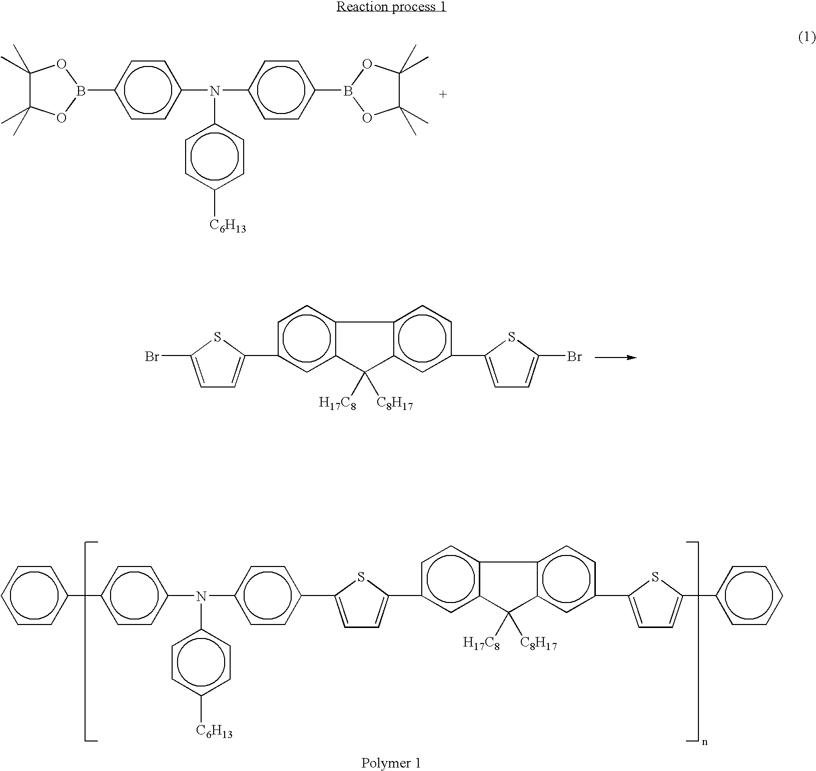

Place the following components in a 100 ml flask.

| | |
|---|---|
| Diboron ester derivative illustrated | 0.872 g (1.5 mmol) |
| in the reaction process 1 | |
| Dibromo derivative illustrated in the | 1.069 g (1.5 mmol) |
| reaction process 1 | |
| Aliquat 336 (manufactured by | 12.1 mg (0.03 mmol) |
| Sigma-Aldrich Corp.) as | |
| a phase transfer catalyst | |
| Phenyl boronic acid | 5.5 mg (0.045 mmol) |

Add 4.33 mg (0.00375 mmol) of tetrakis triphenyl phosphine palladium and 11 ml of toluene thereto. Subsequent to nitrogen gas replacement, add 3.1 ml of 2M-sodium carbonate. After a 17 hour reflux, add 118 mg (0.75 mmol) of bromobenzene for termination reaction followed by an 8 hour flux. After cooling down the reaction solution to room temperature, drop the organic layer therein in a solvent mixture of methanol and water for re-precipitation to obtain a polymer. Prepare a dichloromethane solution of the polymer and sufficiently wash the solution with deionized water. Prepare a tetrahydrofuran solution thereof and drop the solution in methanol for re-precipitation to purify the polymer. The yield of the thus obtained polymer 1 is 1.20 g and the yield ratio thereof is 91%.

The number average molecular weight of the polymer 1 in polystyrene conversion number measured by Gel Permeation Chromatography (GPC) is 48,200. The weight average molecular weight thereof is 134,600.

The glass transition temperature of the polymer 1 obtained using differential scanning calorimetry measurement is 122.1° C.

Elemental analysis (calculated values in parenthesis): C, 83.04% (83.23%), H, 8.05% (7.90%), N, 1.53% (1.59%), S: 7.49% (7.28%).

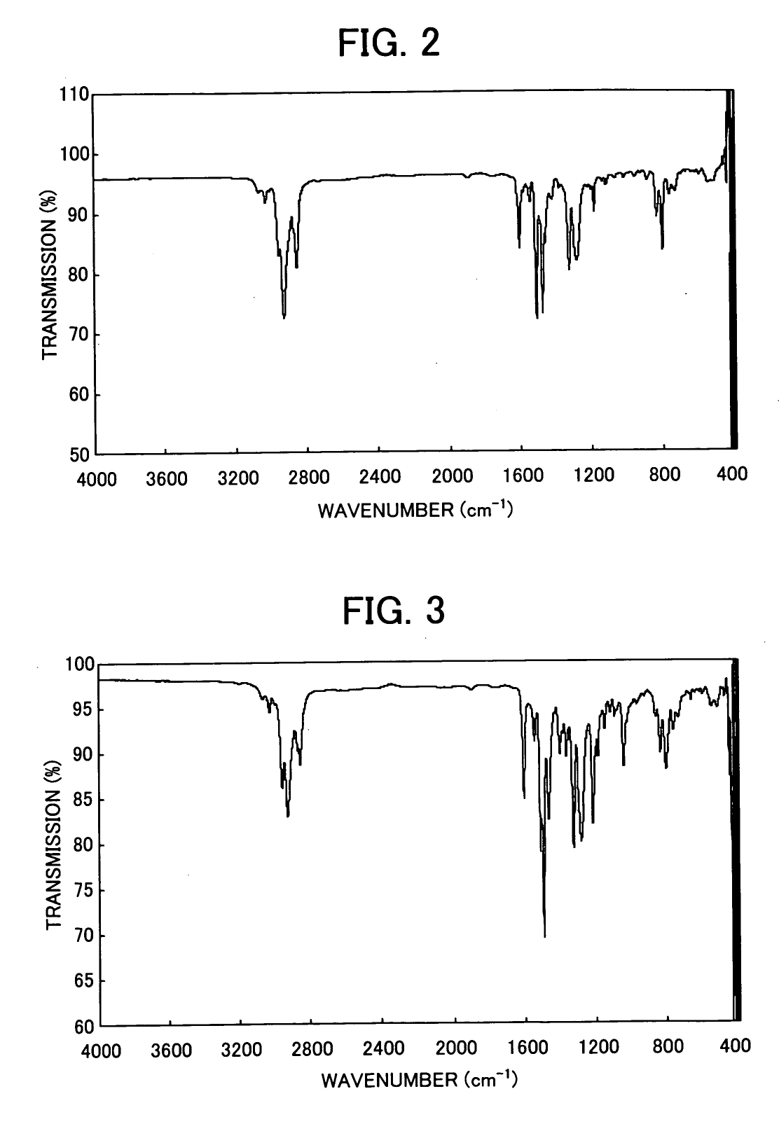

An infrared absorption spectrum (NaCl casting film) of the polymer 1 is illustrated in FIG. 2.

### Example 2

Synthesis of Polymer 2

Polymer 2 is prepared by polymerization under the following conditions along with the following reaction process 2.

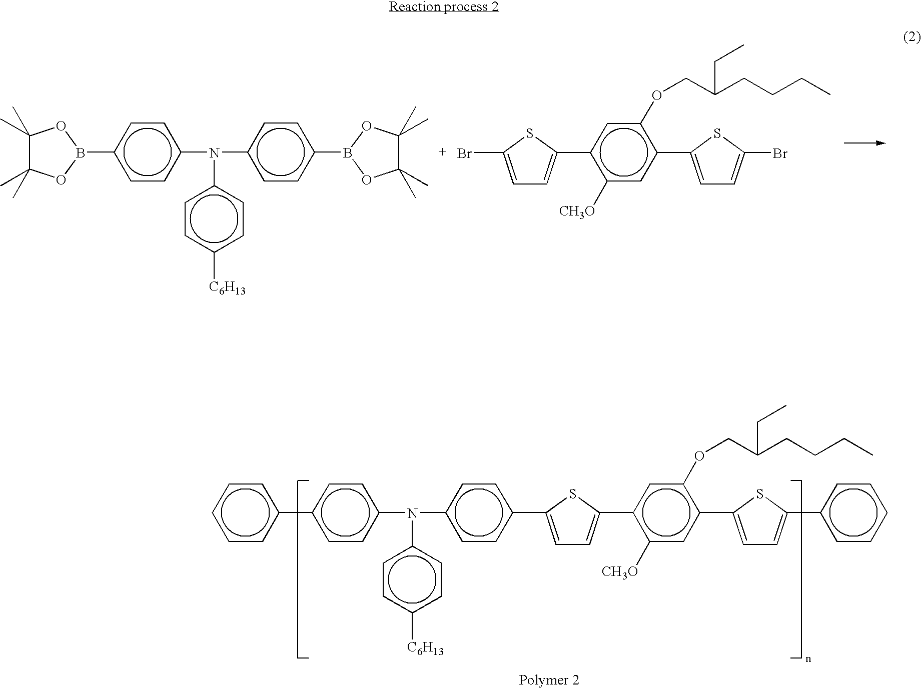

Place the following components in a 100 ml flask.

| | |
|---|---|
| Diboron ester derivative illustrated in | 0.872 g (1.5 mmol) |
| the reaction process 2 | |
| Dibromo derivative illustrated in the | 0.838 g (1.5 mmol) |
| reaction process 2 | |
| Aliquat 336 (manufactured by Sigma-Aldrich | 12.1 mg (0.03 mmol) |
| Corp.) as a phase transfer catalyst | |
| Phenyl boronic acid | 5.5 mg (0.045 mmol) |

Add 4.33 mg (0.00375 mmol) of tetrakis triphenyl phosphine palladium and 11 ml of toluene thereto. Subsequent to nitrogen gas replacement, add 3.1 ml of 2M-sodium carbonate. After a 20 hour reflux, add 118 mg (0.75 mmol) of bromobenzene for termination reaction followed by a 6 hour flux. After cooling down the reaction solution to room temperature, drop the organic layer therein in a solvent mixture of methanol and water for re-precipitation to obtain a polymer. Prepare a dichloromethane solution of the polymer and sufficiently wash the solution with de-ionized water. Prepare a tetrahydrofuran solution thereof and drop the solution in methanol for re-precipitation to purify the polymer. The yield of the thus obtained polymer 2 is 1.07 g and the yield ratio thereof is 98%.

The number average molecular weight of the polymer 2 in polystyrene conversion number measured by Gel Permeation Chromatography (GPC) is 5,900. The weight average molecular weight thereof is 11,800.

The glass transition temperature of the polymer 2 obtained using differential scanning calorimetry measurement is 108.3° C.

Elemental analysis (calculated values in parenthesis): C, 77.46% (77.75%), H, 7.12% (7.08%), N, 1.79% (1.93%), S: 8.69% (8.83%).

An infrared absorption spectrum (NaCl casting film) of the polymer 2 is illustrated in FIG. 3.

### Example 3

Synthesis of Polymer 3

Polymer 3 is prepared by polymerization under the following conditions along with the following reaction process 3.

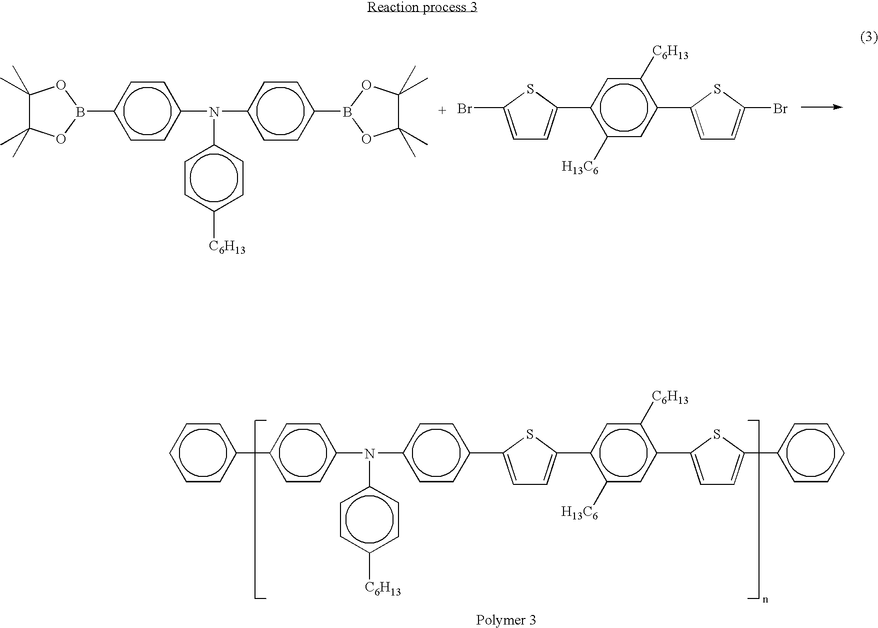

Place the following components in a 100 ml flask.

| | |
|---|---|
| Diboron ester derivative illustrated in the | 0.872 g (1.5 mmol) |
| reaction process 3 | |
| Dibromo derivative illustrated in the | 0.853 g (1.5 mmol) |
| reaction process 3 | |
| Aliquat 336 (manufactured by Sigma-Aldrich | 12.1 mg (0.03 mmol) |
| Corp.) as a phase transfer catalyst | |
| Phenyl boronic acid | 5.5 mg (0.045 mmol) |

Add 4.33 mg (0.00375 mmol) of tetrakis triphenyl phosphine palladium and 11 ml of toluene thereto. Subsequent to nitrogen gas replacement, add 3.1 ml of 2M-sodium carbonate. After a 30 hour reflux, add 118 mg (0.75 mmol) of bromobenzene for termination reaction followed by a 6 hour flux. After cooling down the reaction solution to room temperature, drop the organic layer therein in a solvent mixture of methanol and water for re-precipitation to obtain a polymer. Prepare a dichloromethane solution of the polymer and sufficiently wash the solution with de-ionized water. Prepare a tetrahydrofuran solution thereof and drop the solution in methanol for re-precipitation to purify the polymer. The yield of the thus obtained polymer 3 is 1.10 g and the yield ratio thereof is 99%.

The number average molecular weight of the polymer 3 in polystyrene conversion number measured by Gel Permeation Chromatography (GPC) is 8,500. The weight average molecular weight thereof is 19,400.

The glass transition temperature of the polymer 3 obtained using differential scanning calorimetry measurement is 84.1° C.

Elemental analysis (calculated values in parenthesis): C, 81.30% (81.58%), H, 7.94% (7.80%), N, 1.84% (1.90%), S: 8.48% (8.71%).

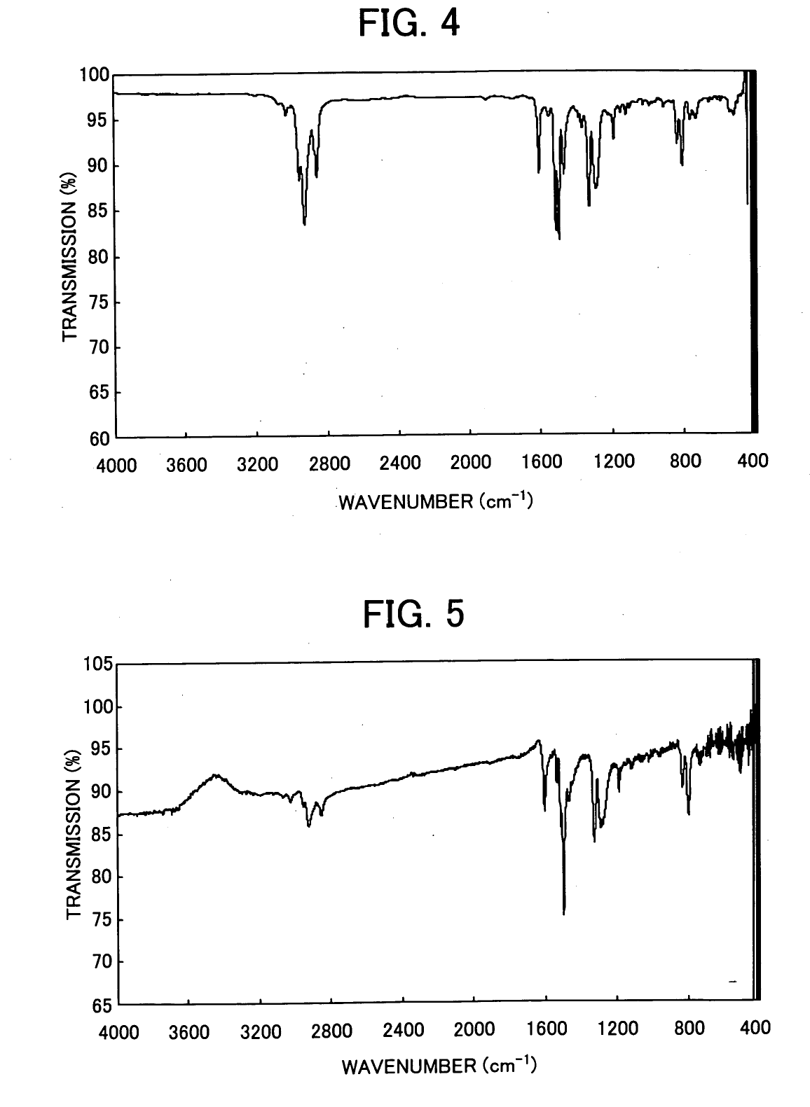

An infrared absorption spectrum (NaCl casting film) of the polymer 3 is illustrated in FIG. 4.

### Example 4

Synthesis of Polymer 4

Polymer 4 is prepared by polymerization under the following conditions along with the following reaction process 4.

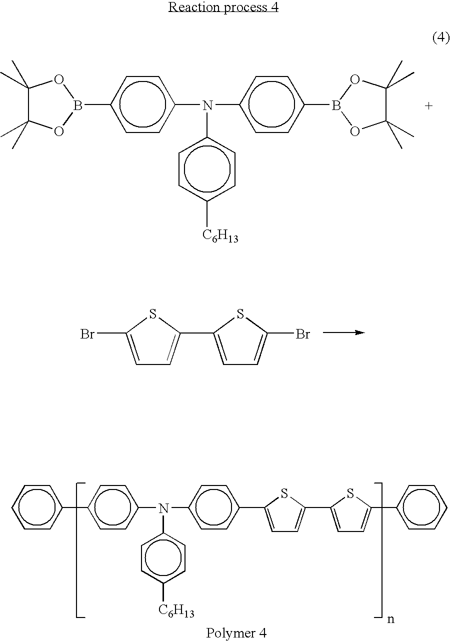

Place the following components in a 100 ml flask.

| | |
|---|---|
| Diboron ester derivative illustrated in the | 1.182 g (2.03 mmol) |
| reaction process 4 | |
| Dibromo derivative illustrated in the reaction | 0.659 g (2.03 mmol) |
| process 4 | |
| Aliquat 336 (manufactured by Sigma-Aldrich | 16.4 mg (0.03 mmol) |
| Corp.) as a phase transfer catalyst | |
| Phenyl boronic acid | 7.4 mg (0.06 mmol) |

Add 5.87 mg (0.0051 mmol) of tetrakis triphenyl phosphine palladium and 14 ml of toluene thereto. Subsequent to nitrogen gas replacement, add 4.1 ml of 2M-sodium carbonate. After a 14 hour reflux, add 157 mg (1.0 mmol) of bromobenzene for termination reaction followed by a 6 hour flux. After cooling down the reaction solution to room temperature, drop the organic layer therein in a solvent mixture of methanol and water for re-precipitation to obtain polymer 4. The obtained polymer is not soluble in tetrahydrofuran and chloroform. The yield of the polymer 4 is 1.00 g and the yield ratio thereof is 100%.

Elemental analysis (calculated values in parenthesis): C, 77.90% (78.17%), H, 5.87% (5.94%), N, 2.73% (2.85%), S: 13.02% (13.04%).

An infrared absorption spectrum (KBr tablet method) of the polymer 4 is illustrated in FIG. 5.

### Example 5

Synthesis of Polymer 3-2

Polymer 3-2 is prepared by polymerization under the following conditions along with the following reaction process 3-2.

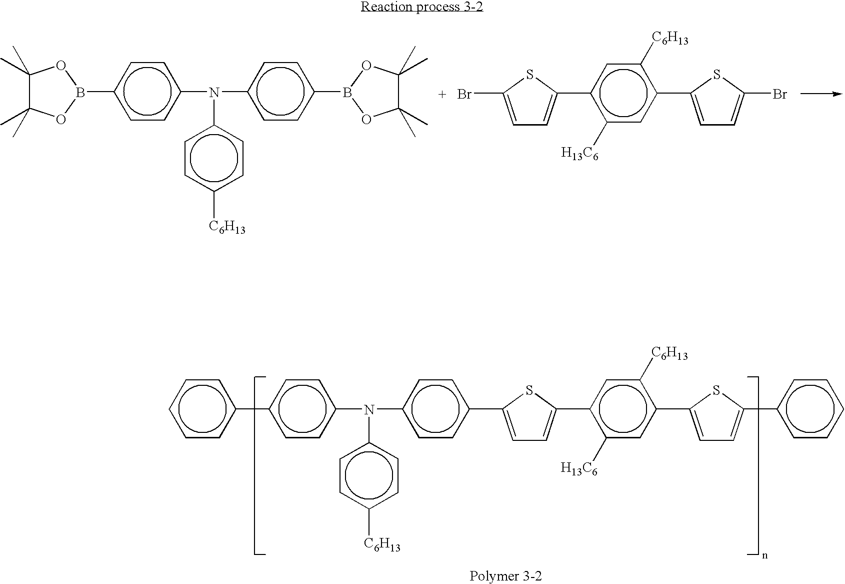

Place the following components in a 50 ml flask.

| | |
|---|---|
| Diboron ester derivative illustrated in the | 0.872 g (1.5 mmol) |
| reaction process 3-2 | |
| Dibromo derivative illustrated in the | 0.853 g (1.5 mmol) |
| reaction process 3-2 | |
| Aliquat 336 (manufactured by Sigma-Aldrich | 12.1 mg (0.03 mmol) |
| Corp.) as a phase transfer catalyst | |

Add 8.7 mg (0.00752 mmol) of tetrakis triphenyl phosphine palladium and 6 ml of toluene thereto. Subsequent to nitrogen gas replacement, add 3.5 ml of 2M-sodium carbonate. After a 13 hour reflux, for termination reaction, add 73 mg (0.6 mmol) of phenyl boronic acid followed by a 5 hour reflux, and further add 109 mg (0.69 mmol) of bromobenzene followed by a 4 hour flux. After cooling down the reaction solution to room temperature, drop the organic layer therein in a solvent mixture of methanol and water for re-precipitation to obtain a polymer. Prepare a chloroform solution of the polymer and sufficiently wash the solution with de-ionized water. Prepare a tetrahydrofuran solution thereof and drop the solution in methanol for re-precipitation to purify the polymer. The yield of the thus obtained polymer 3-2 is 1.07 g and the yield ratio thereof is 97%.

The number average molecular weight of the polymer 3-2 in polystyrene conversion number measured by Gel Permeation Chromatography (GPC) is 42,600. The weight average molecular weight thereof is 164,600.

Elemental analysis (calculated values in parenthesis): C, 81.42% (81.58%), H, 8.01% (7.80%), N, 1.92% (1.90%), S: 8.64% (8.71%).

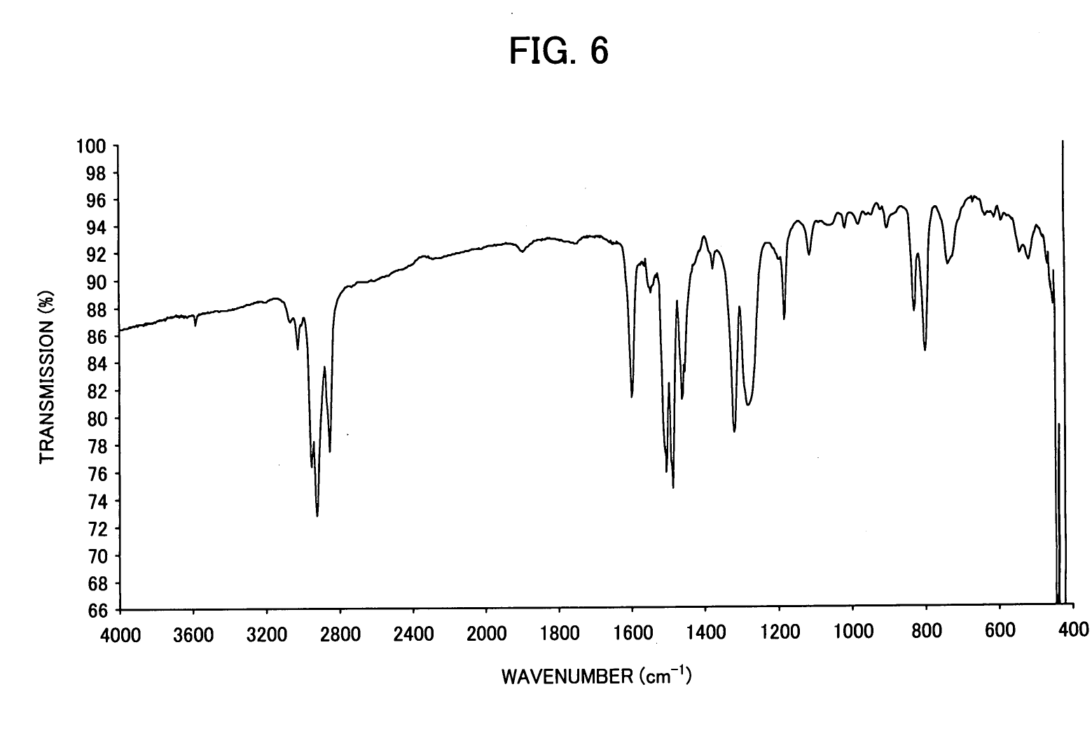

An infrared absorption spectrum (NaCl casting film) of the polymer 3 is illustrated in FIG. 6.

### Example 6

Synthesis of Polymer 5

Polymer 5 is prepared by polymerization under the following conditions along with the following reaction process 5.

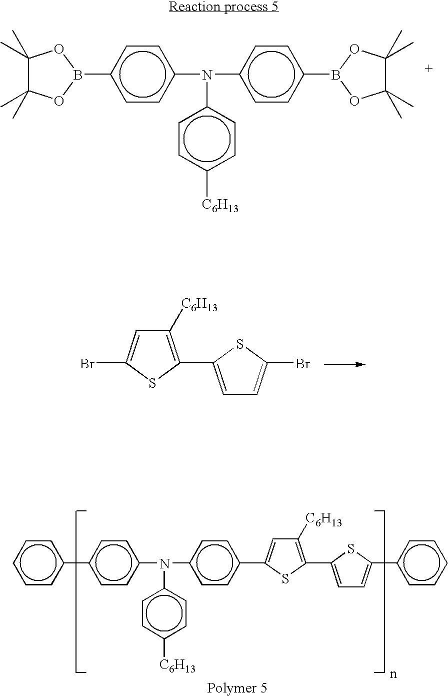

Place the following components in a 50 ml flask.

| | |
|---|---|
| Diboron ester derivative illustrated in the | 0.872 g (1.5 mmol) |
| reaction process 5 | |
| Dibromo derivative illustrated in the | 0.612 g (1.5 mmol) |
| reaction process 5 | |
| Aliquat 336 (manufactured by Sigma-Aldrich | 13.4 mg (0.033 mmol) |
| Corp.) as a phase transfer catalyst | |

Add 8.7 mg (0.0075 mmol) of tetrakis triphenyl phosphine palladium and 6.2 ml of toluene thereto. Subsequent to nitrogen gas replacement, add 3.5 ml of 2M-sodium carbonate. After a 13 hour reflux, for termination reaction, add 73 mg (0.6 mmol) of phenyl boronic acid followed by a 5 hour reflux, and further add 109 mg (0.69 mmol) of bromobenzene followed by a 4 hour flux. After cooling down there action solution to room temperature, drop the organic layer therein in a solvent mixture of methanol and water for re-precipitation to obtain a polymer. Prepare a chloroform solution of the polymer and sufficiently wash the solution with de-ionized water. Prepare a tetrahydrofuran solution thereof and drop the solution in methanol for re-precipitation to purify the polymer. The yield of the thus obtained polymer 5 is 0.844 g and the yield ratio thereof is 98%.

The number average molecular weight of the polymer 5 in polystyrene conversion number measured by Gel Permeation Chromatography (GPC) is 40,900. The weight average molecular weight thereof is 176,400.

Elemental analysis (calculated values in parenthesis): C, 78.98% (79.26%), H, 7.22% (7.18%), N, 2.57% (2.43%), S: 11.04% (11.13%).

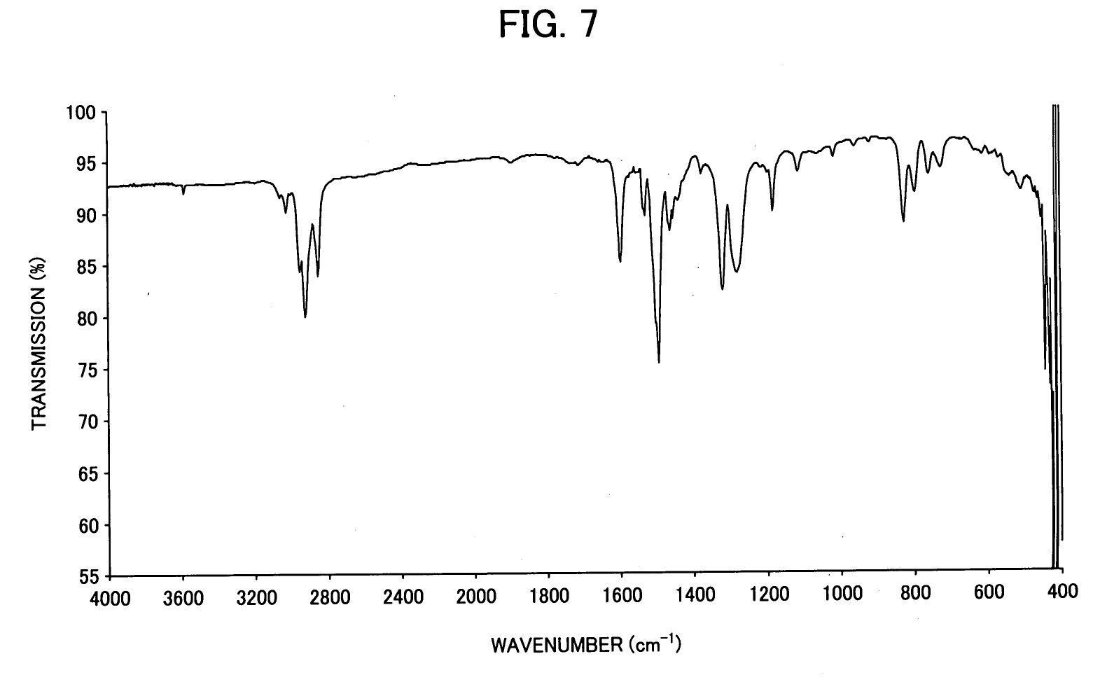

An infrared absorption spectrum (NaCl casting film) of the polymer 5 is illustrated in FIG. 7.

### Example 7

Synthesis of Polymer 6

Polymer 6 is prepared by polymerization under the following conditions along with the following reaction process 6.

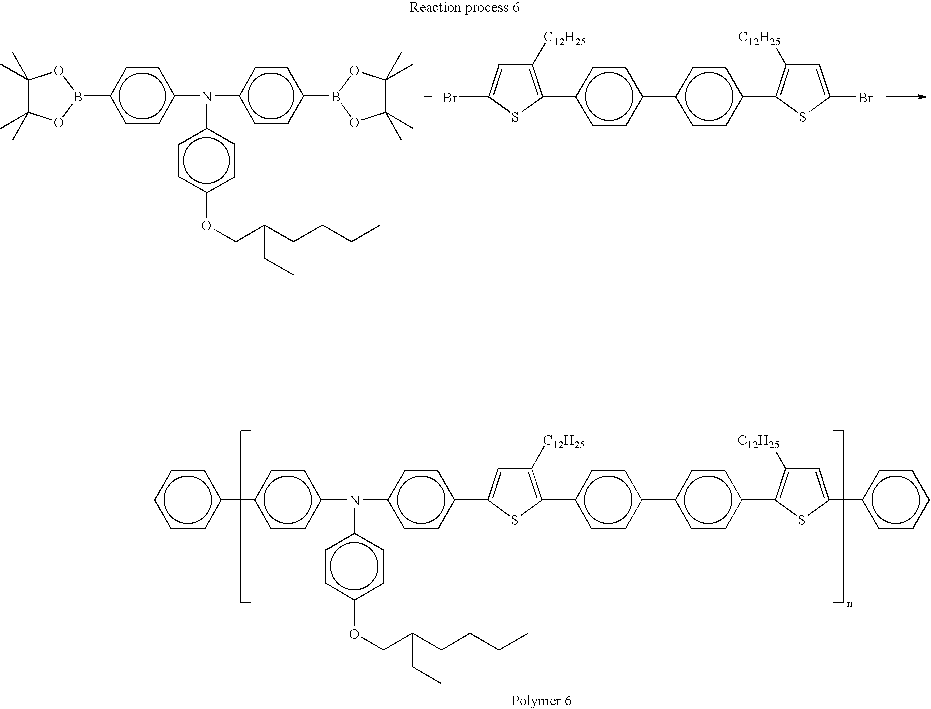

Place the following components in a 50 ml flask.

| | |
|---|---|
| Diboron ester derivative illustrated in the | 0.938 g (1.5 mmol) |
| reaction process 6 | |
| Dibromo derivative illustrated in the | 1.219 g (1.5 mmol) |
| reaction process 6 | |
| Aliquat 336 (manufactured by Sigma-Aldrich | 12.6 mg (0.03 mmol) |
| Corp.) as a phase transfer catalyst | |

Add 8.7 mg (0.00752 mmol) of tetrakis triphenyl phosphine palladium and 6.2 ml of toluene thereto. Subsequent to nitrogen gas replacement, add 3.5 ml of 2M-sodium carbonate. After a 4 hour reflux, for termination reaction, add 73 mg (0.6 mmol) of phenyl boronic acid followed by a 3 hour reflux, and further add 118 mg (0.75 mmol) of bromobenzene followed by a 3 hour flux. After cooling down the reaction solution to room temperature, drop the organic layer therein in a solvent mixture of methanol and water for re-precipitation to obtain a polymer. Prepare a chloroform solution of the polymer and sufficiently wash the solution with de-ionized water. Prepare a tetrahydrofuran solution thereof and drop the solution in methanol for re-precipitation to purify the polymer. The yield of the thus obtained polymer 6 is 1.23 g and the yield ratio thereof is 80%.

The number average molecular weight of the polymer 6 in polystyrene conversion number measured by Gel Permeation Chromatography (GPC) is 35,700. The weight average molecular weight thereof is 184,300.

Elemental analysis (calculated values in parenthesis): C, 82.35% (82.60%), H, 8.61% (8.76%), N, 1.45% (1.37%), S: 6.10% (6.26%).

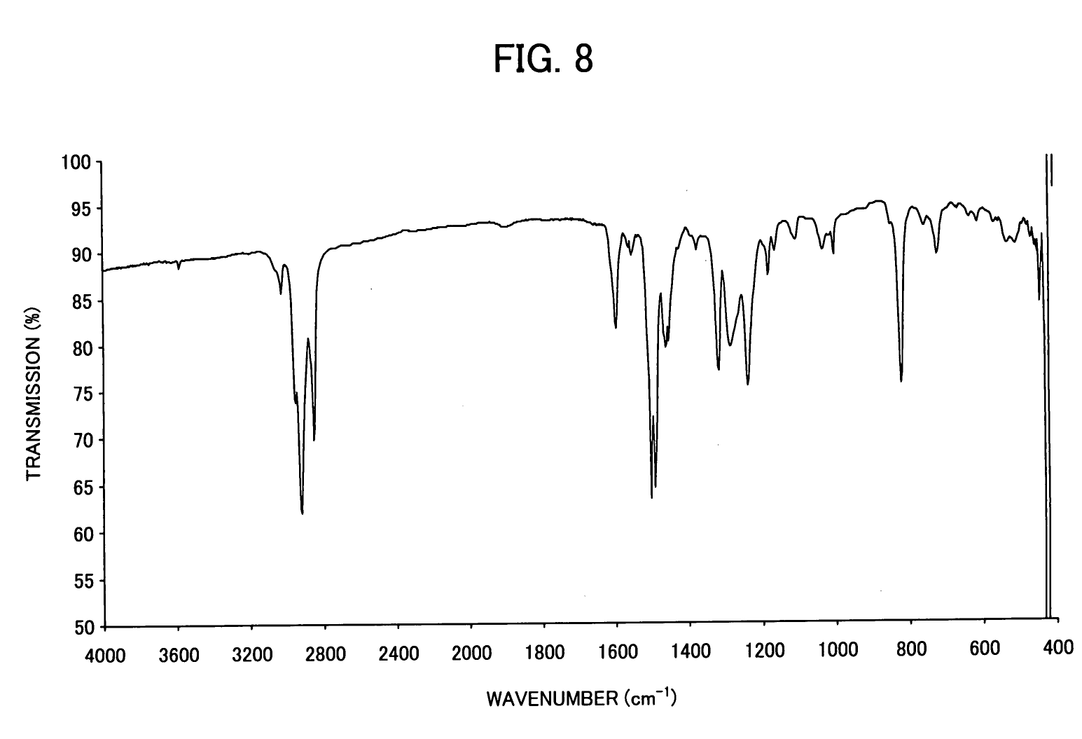

An infrared absorption spectrum (NaCl casting film) of the polymer 6 is illustrated in FIG. 8.

### Example 8

Synthesis of Polymer 7

Polymer 7 is prepared by polymerization under the following conditions along with the following reaction process 7.

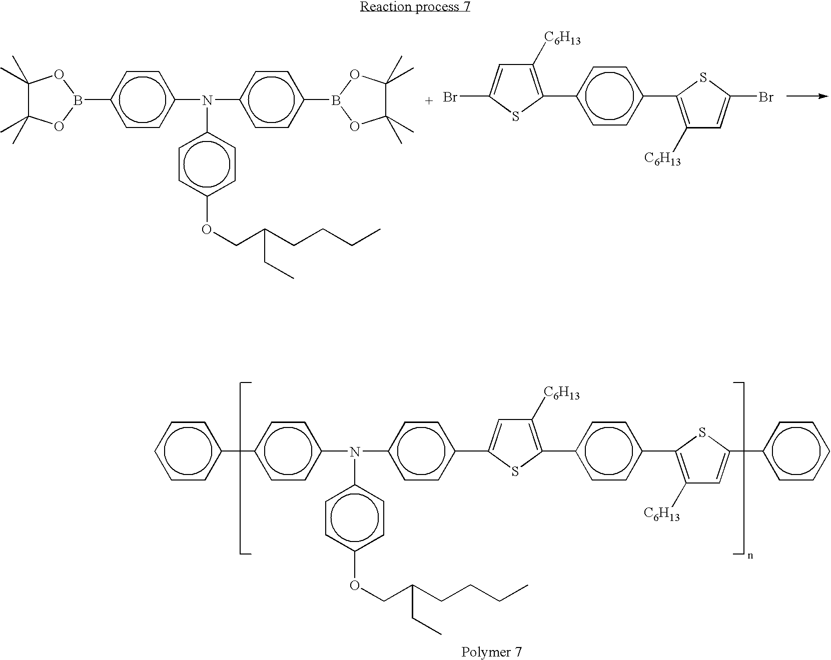

Place the following components in a 50 ml flask.

| | |
|---|---|
| Diboron ester derivative illustrated in the | 0.938 g (1.5 mmol) |
| reaction process 7 | |
| Dibromo derivative illustrated in the | 0.852 g (1.5 mmol) |
| reaction process 7 | |
| Aliquat 336 (manufactured by Sigma-Aldrich | 12.8 mg (0.03 mmol) |
| Corp.) as a phase transfer catalyst | |

Add 8.7 mg (0.00752 mmol) of tetrakis triphenyl phosphine palladium and 6.2 ml of toluene thereto. Subsequent to nitrogen gas replacement, add 3.5 ml of 2M-sodium carbonate. After a 4 hour reflux, for termination reaction, add 73 mg (0.6 mmol) of phenyl boronic acid followed by a 3 hour reflux, and further add 118 mg (0.75 mmol) of bromobenzene followed by a 3 hour flux. After cooling down the reaction solution to room temperature, drop the organic layer therein in a solvent mixture of methanol and water for re-precipitation to obtain a polymer. Prepare a chloroform solution of the polymer and sufficiently wash the solution with de-ionized water. Prepare a tetrahydrofuran solution thereof and drop the solution in methanol for re-precipitation to purify the polymer. The yield of the thus obtained polymer 7 is 0.76 g and the yield ratio thereof is 65%.

The number average molecular weight of the polymer 7 in polystyrene conversion number measured by Gel Permeation Chromatography (GPC) is 29,700. The weight average molecular weight thereof is 154,700.

Elemental analysis (calculated values in parenthesis): C, 79.87% (80.05%), H, 7.99% (7.88%), N, 1.74% (1.80%), S: 8.35% (8.22%).

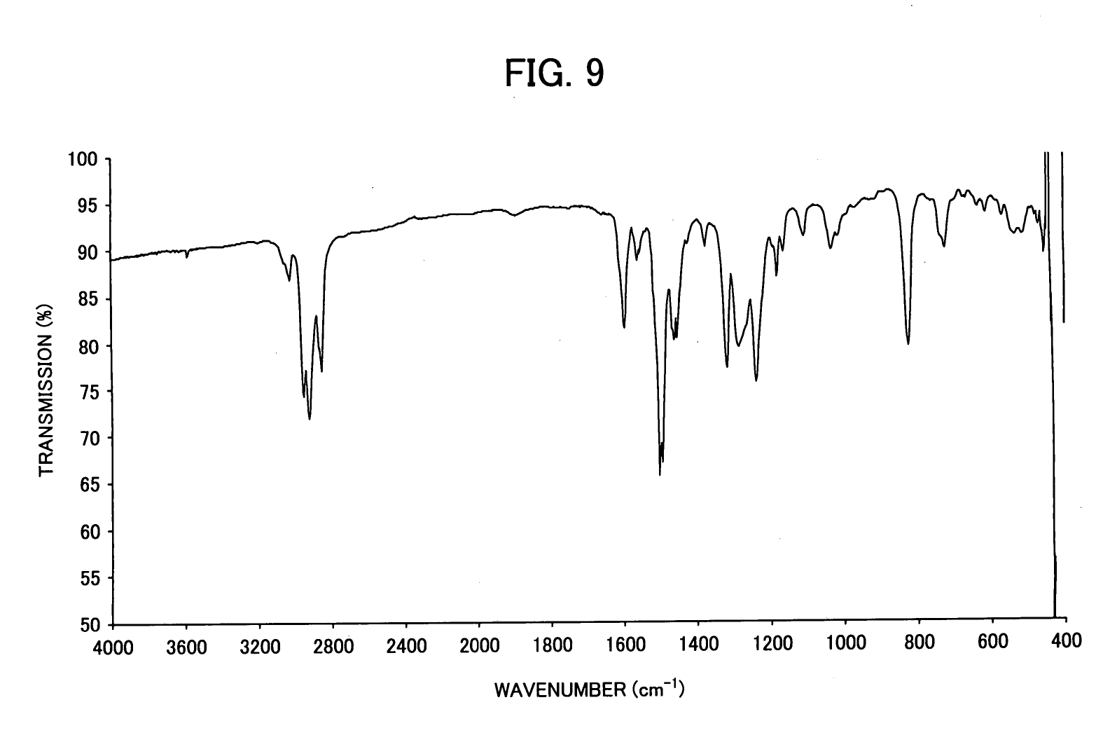

An infrared absorption spectrum (NaCl casting film) of the polymer 7 is illustrated in FIG. 9.

Example of Manufacturing Substrate for Evaluating Organic Thin Film Transistor

Form an insulating layer of SiO₂ having a thickness of 200 nm by thermal oxidizing the surface of a silicon substrate having a 30 mm p-doped square. Cover one side thereof with a resist film (TSMR8800 manufactured by Tokyo Ohka Kogyo Co., Ltd.) and remove the oxidized film on the other side by fluorinated acid. Deposit aluminum having a thickness of 300 nm on the side from which the oxidized film is removed. Thereafter, remove the resist film by acetone to obtain a substrate for evaluating an organic thin film transistor.

### Example 9

The following thin film transistor is manufactured on the substrate for evaluating an organic thin film transistor manufactured by the method described above using the polymer 1.

Spin-coat and dry a solution formed of a solvent mixture of tetrahydrofuran (THF) and paraxylene with a ratio of 8 to 2 containing the polymer 1 in an amount of about 1% by weight based on the weight of the solution on the substrate to manufacture an organic semiconductor layer having a layer thickness of 30 nm.

Deposit gold to form a source electrode and a drain electrode having a layer thickness of 100 nm so that an organic thin film transistor can have a channel length of 30 μm and a channel width of 10 mm.

Further, to confirm the reproducibility of the characteristics of the organic thin film transistor, another organic thin film transistor is manufactured in the same manner.

The thus manufactured organic thin film transistors have a structure illustrated in FIG. 1D. The p-doped silicon substrate is used as a gate electrode together with an aluminum thin layer provided to the bottom of the substrate.

The electric field-effect mobility, which is the characteristic of the organic thin film transistor, is measured.

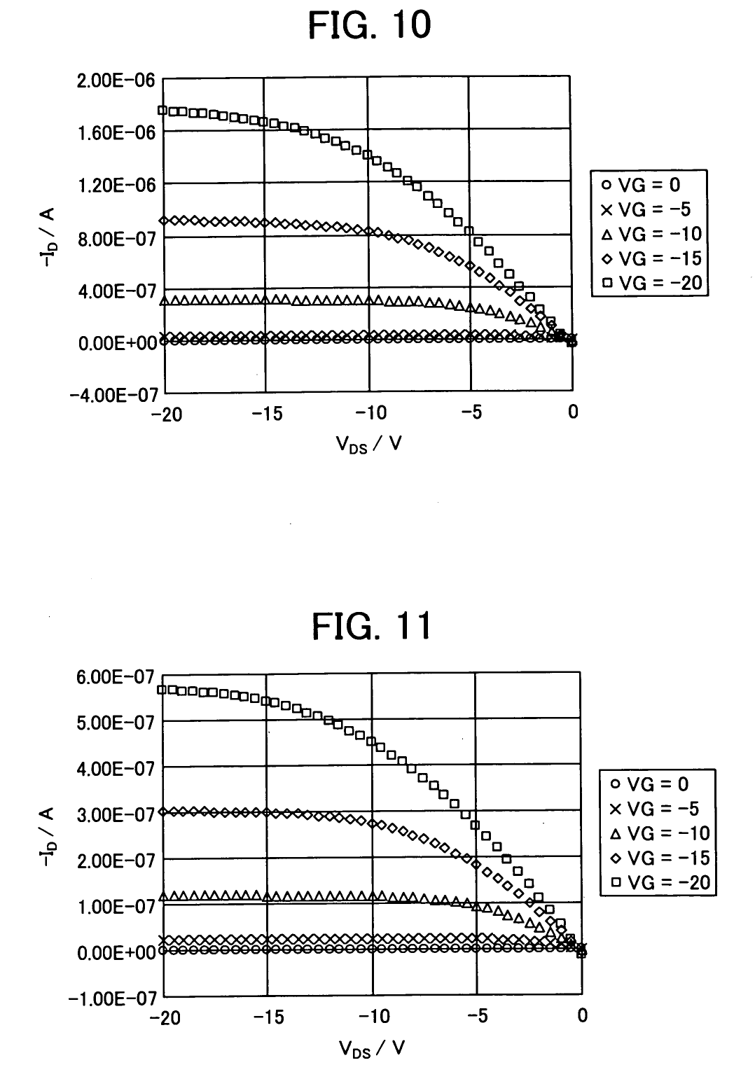

The measuring results of the transistor characteristic of this device are illustrated in FIG. 10. In FIG. 10, V_{ds} represents the source-drain voltage.

The following relationship is used to calculate the electric field-effect mobility of the organic thin film transistor.
I_{ds}=μCᵢₙW(V_{G}−V_{TH})²/2L

In the relationship, Cᵢₙ represents the capacitance per unit area of the gate insulating layer, W represents the channel width, L represents the channel length, V_{G} represents the gate voltage, I_{ds} represents the source-drain current (I_{d} in FIGS. 9 to 16 is the same as I_{DS}), and μ represents the mobility, V_{TH} represents a threshold voltage of the gate above which the channel starts being formed.

The electric field-effect mobility of the manufactured organic thin film transistors is 2.4×10⁻³ cm²/Vs and 1.9×10⁻³ cm²/Vs.

There are few variances among the elements with regard to the transistors. It can be concluded that the reproducibility of the transistor characteristic of these transistors is good.

### Example 10

Two organic thin film transistors are manufactured in the same manner as in Example 9 except that spin coating is performed using a toluene solution containing the polymer 1 in an amount of 1.0% by weight based on the weight of the solution.

The electric field-effect mobility of the manufactured organic transistors measured is 1.9×10⁻³ cm²/Vs and 2.0×10⁻³ cm²/Vs.

There are few variances among the elements with regard to the transistors and the reproducibility of the transistor characteristic of these transistors is good.

As seen in Examples 9 and 10, it is found that an organic thin film transistor having a good reproducibility and few characteristic variances can be provided regardless of different solvents.

### Example 11

Two organic thin film transistors are manufactured in the same manner as in Example 9 except that spin coating is performed using a solution of a solvent mixture of tetrahydrofuran (THF) and paraxylene with a ratio of 8 to 2 containing the polymer 2 in an amount of 1.0% by weight based on the weight of the solution.

The measuring results of the transistor characteristics of the device are illustrated in FIG. 11.

The electric field-effect mobility of the manufactured organic transistors measured is 4.2×10⁻⁴ cm²/Vs and 4.3×10⁻⁴ cm²/Vs.

There are few variances among the elements of the transistors and these transistors have transistor characteristics with a good reproducibility.

### Example 12

Two organic thin film transistors are manufactured in the same manner as in Example 9 except that spin coating is performed using a toluene solution containing the polymer 2 in an amount of 1.0% by weight based on the weight of the solution.

The electric field-effect mobility of the manufactured organic transistors measured is 4.3×10⁻⁴ cm²/Vs and 4.1×10⁻⁴ cm²/Vs.

There are few variances among the elements with regard to the transistors and the reproducibility of the transistor characteristic of these transistors is good.

According to Examples 11 and 12, it is found to be possible to provide an organic thin film transistor having a good reproducibility and few characteristic variances regardless of different solvents.

### Example 13

Two organic thin film transistors are manufactured in the same manner as in Example 9 except that spin coating is performed using a solution of a solvent mixture of tetrahydrofuran (THF) and paraxylene with a ratio of 8 to 2 containing the polymer 3 in an amount of 1.0% by weight based on the weight of the solution.

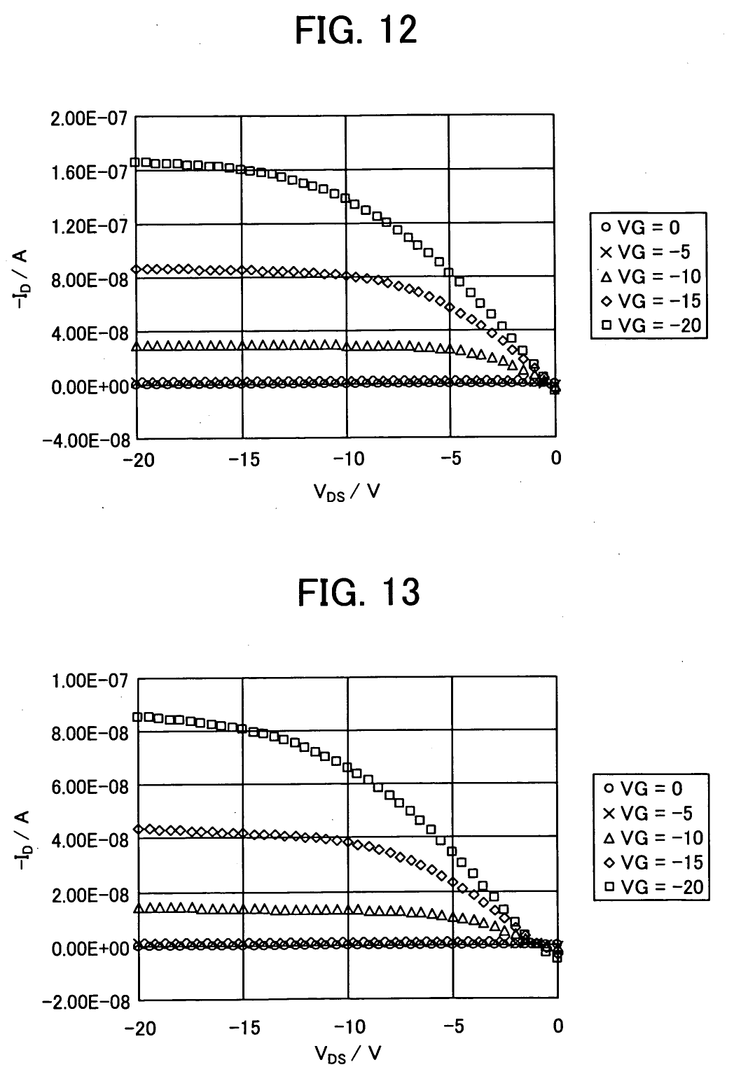

The measuring results of the transistor characteristics of the device are illustrated in FIG. 12.

The electric field-effect mobility of the manufactured organic transistors measured is 1.8×10⁻⁴ cm²/Vs and 1.3×10⁻⁴ cm²/Vs.

There are few variances among the elements with regard to the transistors and the reproducibility of the transistor characteristic of these transistors is good.

### Example 14

Two organic thin film transistors are manufactured in the same manner as in Example 9 except that spin coating is performed using a toluene solution containing the polymer 3 in an amount of 1.0% by weight based on the weight of the solution.

The electric field-effect mobility of the manufactured organic transistors measured is 1.4×10⁻⁴ cm²/Vs and 1.7×10⁻⁴ cm²/Vs.

There are few variances among the elements with regard to the transistors and the reproducibility of the transistor characteristic of these transistors is good.

According to Examples 13 and 14, it is found to be possible to provide an organic transistor having a good reproducibility and few characteristic variances regardless of different solvents.

### Example 15

Two organic thin film transistors are manufactured in the same manner as in Example 9 except that spin coating is performed using a solution of a solvent mixture of tetrahydrofuran (THF) and paraxylene with a ratio of 8 to 2 containing the polymer 3-2 in an amount of 1.0% by weight based on the weight of the solution and the channel length between the source electrode and the drain electrode is 50 μm and the channel width is 9 mm.

The measuring results of the transistor characteristics of the device are illustrated in FIG. 13.

The electric field-effect mobility of the manufactured organic thin film transistors measured is 2.0×10⁻⁴ cm²/Vs and 1.8×10⁻⁴ cm²/Vs.

There are few variances among the elements with regard to the transistors and the reproducibility of the transistor characteristic of these transistors is good.

### Example 16

Two organic thin film transistors are manufactured in the same manner as in Example 9 except that spin coating is performed using a toluene solution containing the polymer 3-2 in an amount of 1.0% by weight based on the weight of the solution and the channel length between the source electrode and the drain electrode is 50 μm and the channel width is 9 mm.

The electric field-effect mobility of the manufactured organic transistors measured is 1.8×10⁻⁴ cm²/Vs and 1.9×10⁻⁴ cm²/Vs.

There are few variances among the elements with regard to the transistors and the reproducibility of the transistor characteristic of these transistors is good.

According to Examples 15 and 16, it is found to be possible to provide an organic transistor having a good reproducibility and few characteristic variances regardless of different solvents.

### Example 17

Two organic thin film transistors are manufactured in the same manner as in Example 9 except that spin coating is performed using a solution of a solvent mixture of tetrahydrofuran (THF) and paraxylene with a ratio of 8 to 2 containing the polymer 5 in an amount of 1.0% by weight based on the weight of the solution and the channel length between the source electrode and the drain electrode is 50 μm and the channel width is 9 mm.

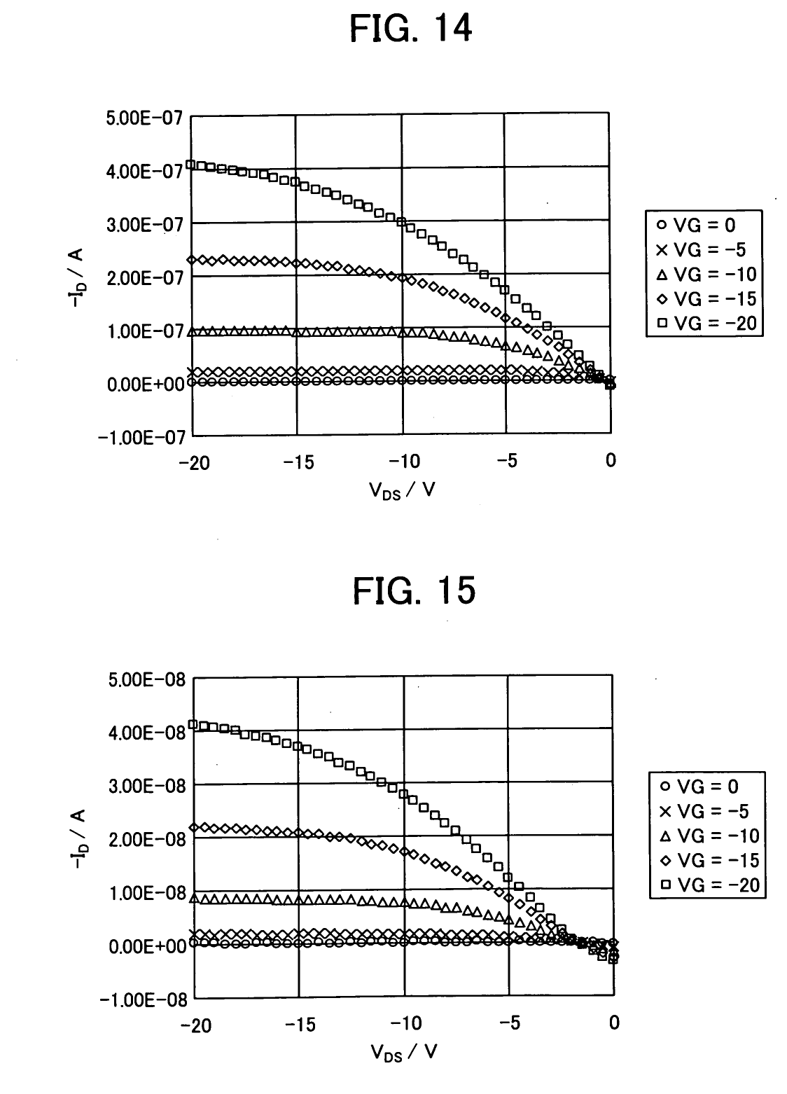

The measuring results of the transistor characteristics of the device are illustrated in FIG. 14.

The electric field-effect mobility of the manufactured organic transistors measured is 6.1×10⁻⁴ cm²/Vs and 6.7×10⁻⁴ cm²/Vs.

There are few variances among the elements with regard to the transistors and the reproducibility of the transistor characteristic of these transistors is good.

### Example 18

Two organic thin film transistors are manufactured in the same manner as in Example 9 except that spin coating is performed using a toluene solution containing the polymer 5 in an amount of 1.0% by weight based on the weight of the solution and the channel length between the source electrode and the drain electrode is 50 μm and the channel width is 9 mm.

The electric field-effect mobility of the manufactured organic transistors measured is 6.2×10⁻⁴ cm²/Vs and 6.4×10⁻⁴ cm²/Vs.

There are few variances among the elements with regard to the transistors and these transistors have transistor characteristics with a good reproducibility.

According to Examples 17 and 18, it is found to be possible to provide an organic transistor having a good reproducibility and few characteristic variances regardless of different solvents.

### Example 19

Two organic thin film transistors are manufactured in the same manner as in Example 9 except that spin coating is performed using a solution of a solvent mixture of tetrahydrofuran (THF) and paraxylene with a ratio of 8 to 2 containing the polymer 6 in an amount of 1.0% by weight based on the weight of the solution.

The measuring results of the transistor characteristics of the device are illustrated in FIG. 15.

The electric field-effect mobility of the manufactured organic transistors measured is 3.9×10⁻⁵ cm²/Vs and 4.2×10⁻⁵ cm²/Vs.

There are few variances among the elements with regard to the transistors and the reproducibility of the transistor characteristic of these transistors is good.

### Example 20

Two organic thin film transistors are manufactured in the same manner as in Example 9 except that spin coating is performed using a toluene solution containing the polymer 6 in an amount of 1.0% by weight based on the weight of the solution.

The electric field-effect mobility of the manufactured organic transistors measured is 4.0×10⁻⁵ cm²/Vs and 3.8×10⁻⁵ cm²/Vs.

There are few variances among the elements with regard to the transistors and these transistors have transistor characteristics with a good reproducibility.

According to Examples 19 and 20, it is found to be possible to provide an organic transistor having a good reproducibility and few characteristic variances regardless of different solvents.

### Example 21

Two organic thin film transistors are manufactured in the same manner as in Example 9 except that spin coating is performed using a solution of a solvent mixture of tetrahydrofuran (THF) and paraxylene with a ratio of 8 to 2 containing the polymer 7 in an amount of 1.0% by weight based on the weight of the solution.

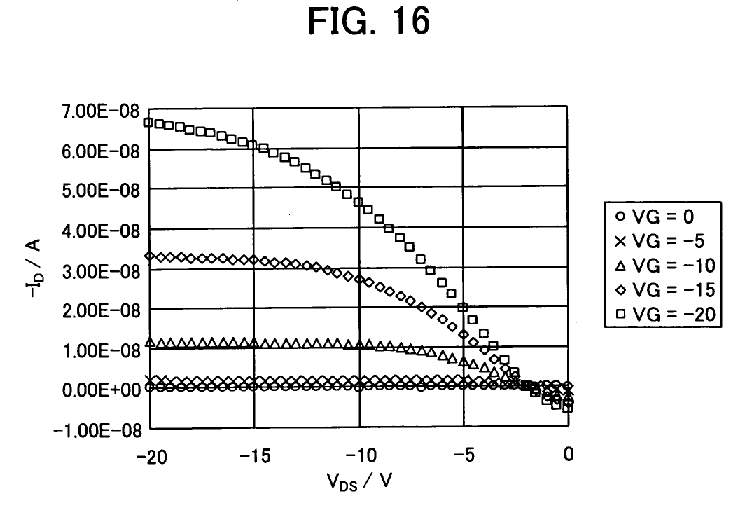

The measuring results of the transistor characteristics of the device are illustrated in FIG. 16.

The electric field-effect mobility of the manufactured organic transistors measured is 9.3×10⁻⁵ cm²/Vs and 8.7×10⁻⁵ cm²/Vs.

There are few variances among the elements with regard to the transistors and the reproducibility of the transistor characteristic of these transistors is good.

### Example 22

Two organic thin film transistors are manufactured in the same manner as in Example 9 except that spin coating is performed using a toluene solution containing the polymer 7 in an amount of 1.0% by weight based on the weight of the solution.

The electric field-effect mobility of the manufactured organic transistors measured is 8.5×10⁻⁵ cm²/Vs and 8.8×10⁻⁵ cm²/Vs.

There are few variances among the elements with regard to the transistors and these transistors have transistor characteristics with a good reproducibility.

According to Examples 21 and 22, it is found to be possible to provide an organic transistor having a good reproducibility and few characteristic variances regardless of different solvents.

### Comparative Example 1

Two organic transistors are manufactured in the same manner as in Example 9 except that a xylene solution containing a copolymer of 9,9-dioctylfluorene and bithiophene in an amount of 0.5% by weight based on the weight of the solution is spin-coated on the SiO₂ insulating layer.

The electric field-effect mobility of the manufactured organic thin film transistors measured is 5.1×10⁻⁴ cm²/Vs and 1.6×10⁻³ cm²/Vs.

### Comparative Example 2

Two organic transistors are manufactured in the same manner as in Example 9 except that a tetrahydrofuran solution containing a copolymer of 9,9-dioctylfluorene and bithiophene in an amount of 0.5% by weight based on the weight of the solution is spin-coated on the SiO₂ insulating layer.

The electric field-effect mobility of the manufactured organic thin film transistors measured is 1.3×10⁻⁴ cm²/Vs and 5.2×10⁻⁴ cm²/Vs.

As seen in the results, the organic thin film transistors formed using the copolymer of 9,9-dioctylfluorene and bithiophene have a variance in the transistor characteristic. On the other hand, the reproducibility of the transistor characteristic of the organic thin film transistors of the present invention formed using the organic polymer semiconductor containing the arylamine polymer of the present invention is good and is little affected by the selection of the solvent.

That is, it is found that, according to the present invention, an organic thin film transistor having few variances and a good reproducibility for the transistor characteristic can be provided with an easy manufacturing process.

This document claims priority and contains subject matter related to Japanese Patent Applications Nos. 2005-249285 and 2006-064169, and filed on Aug. 30, 2005 and Mar. 9, 2006, respectively, the entire contents of which are incorporated herein by reference.

Having now fully described the invention, it will be apparent to one of ordinary skill in the art that many changes and modifications can be made thereto without departing from the spirit and scope of the invention as set forth therein.

What is claimed as new and desired to be secured by Letters Patent:

1. An arylamine polymer, comprising:
a repeating unit represented by the following chemical structure (I), 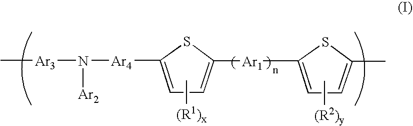
wherein Ar₁, Ar₃, and Ar₄ each, independently, represent a substituted or non-substituted divalent aromatic hydrocarbon group, Ar₂ represents a substituted or non-substituted univalent aromatic hydrocarbon group, R¹ and R² each, independently, represent a hydrogen atom, a substituted or non-substituted alkyl group, a substituted or non-substituted alkoxy group or a substituted or non-substituted alkylthio group, x and y each, independently, represent an integer of from 0 to 2, and n represents 0 or 1.

2. The arylamine polymer according to claim 1, wherein the repeating unit represented by the chemical structure (I) is represented by the following chemical structure (II), 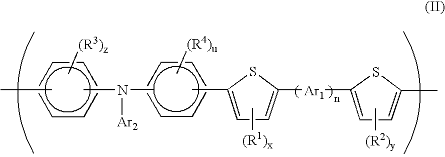
wherein Ar₁ represents a substituted or non-substituted divalent aromatic hydrocarbon group, Ar² represents a substituted or non-substituted univalent aromatic hydrocarbon group, R¹, R², R³ and R⁴ each, independently, represent a hydrogen atom, a substituted or non-substituted alkyl group, a substituted or non-substituted alkoxy group, or a substituted or non-substituted alkylthio group, x and y each, independently, represent an integer of from 0 to 2, z and u each, independently, represent an integer of from 0 to 4, and n represents 0 or 1.

3. The arylamine polymer according to claim 1, wherein the repeating unit represented by the chemical structure (I) is represented by the following chemical structure (III), 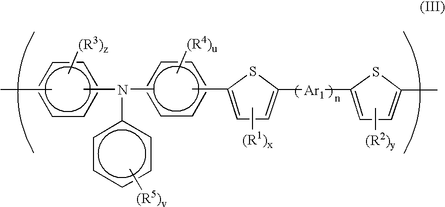
wherein Ar₁ represents a substituted or non-substituted divalent aromatic hydrocarbon group, R¹, R², R³, R⁴, and R⁵ each, independently, represent a hydrogen atom, a substituted or non-substituted alkyl group, a substituted or non-substituted alkoxy group, or a substituted or non-substituted alkylthio group, x and y each, independently, represent an integer of from 0 to 2, z and u each, independently, represent an integer of from 0 to 4, v represents an integer of from 0 to 5 and n represents 0 or 1.

4. The arylamine polymer according to claim 1, wherein R¹ and R² are each, independently, a substituted or unsubstituted alkyl group selected from the group consisting of methyl, ethyl, n-propyl, i-propyl, t-butyl, s-butyl, n-butyl, i-butyl, pentyl, hexyl, heptyl, octyl, nonyl, decyl, 3,7-dimethyloctyl, 2-ethylhexyl, trifluoromethyl, 2-cyanoethyl, benzyl, 4-chlorobenzyl, 4-methyl benzyl, cyclopentyl and cyclohexyl; a substituted or unsubstituted alkoxy group selected from the group consisting of methoxyl, ethoxyl, n-propoxyl, i-propoxyl, t-butoxyl, s-butoxyl, n-butoxyl, i-butoxyl, pentoxyl, hexoxyl, heptoxyl, octoxyl, nonoxyl, decoxyl, 3,7-dimethyloctoxyl, 2-ethylhexoxyl, trifluoromethoxyl, 2-cyanoethoxyl, benzoxyl, 4-chlorobenzoxyl, 4-methyl benzoxyl, cyclopentoxyl and cyclohexoxyl; or a substituted or unsubstituted alkylthio group selected from the group consisting of methylthio, ethylthio, n-propylthio, i-propylthio, t-butylthio, s-butylthio, n-butylthio, i-butylthio, pentylthio, hexylthio, heptylthio, octylthio, nonylthio, decylthio, 3,7-dimethyloctylthio, 2-ethylhexylthio, trifluoromethylthio, 2-cyanoethylthio, benzylthio, 4-chlorobenzylthio, 4-methyl benzylthio, cyclopentylthio and cyclohexylthio.

5. The arylamine polymer according to claim 2, wherein R¹, R², R³, and R⁴ are each, independently, a substituted or unsubstituted alkyl group selected from the group consisting of methyl, ethyl, n-propyl, i-propyl, t-butyl, s-butyl, n-butyl, i-butyl, pentyl, hexyl, heptyl, octyl, nonyl, decyl, 3,7-dimethyloctyl, 2-ethylhexyl, trifluoromethyl, 2-cyanoethyl, benzyl, 4-chlorobenzyl, 4-methyl benzyl, cyclopentyl and cyclohexyl; a substituted or unsubstituted alkoxy group selected from the group consisting of methoxyl, ethoxyl, n-propoxyl, i-propoxyl, t-butoxyl, s-butoxyl, n-butoxyl, i-butoxyl, pentoxyl, hexoxyl, heptoxyl, octoxyl, nonoxyl, decoxyl, 3,7-dimethyloctoxyl, 2-ethylhexoxyl, trifluoromethoxyl, 2-cyanoethoxyl, benzoxyl, 4-chlorobenzoxyl, 4-methyl benzoxyl, cyclopentoxyl and cyclohexoxyl; or a substituted or unsubstituted alkylthio group selected from the group consisting of methylthio, ethylthio, n-propylthio, i-propylthio, t-butylthio, s-butylthio, n-butylthio, i-butylthio, pentylthio, hexylthio, heptylthio, octylthio, nonylthio, decylthio, 3,7-dimethyloctylthio, 2-ethylhexylthio, trifluoromethylthio, 2-cyanoethylthio, benzylthio, 4-chlorobenzylthio, 4-methyl benzylthio, cyclopentylthio and cyclohexylthio.

6. The arylamine polymer according to claim 3, wherein R¹, R², R³, R⁴ and R⁵ are each, independently, a substituted or unsubstituted alkyl group selected from the group consisting of methyl, ethyl, n-propyl, i-propyl, t-butyl, s-butyl, n-butyl, i-butyl, pentyl, hexyl, heptyl, octyl, nonyl, decyl, 3,7-dimethyloctyl, 2-ethylhexyl, trifluoromethyl, 2-cyanoethyl, benzyl, 4-chlorobenzyl, 4-methyl benzyl, cyclopentyl and cyclohexyl; a substituted or unsubstituted alkoxy group selected from the group consisting of methoxyl, ethoxyl, n-propoxyl, i-propoxyl, t-butoxyl, s-butoxyl, n-butoxyl, i-butoxyl, pentoxyl, hexoxyl, heptoxyl, octoxyl, nonoxyl, decoxyl, 3,7-dimethyloctoxyl, 2-ethylhexoxyl, trifluoromethoxyl, 2-cyanoethoxyl, benzoxyl, 4-chlorobenzoxyl, 4-methyl benzoxyl, cyclopentoxyl and cyclohexoxyl; or a substituted or unsubstituted alkylthio group selected from the group consisting of methylthio, ethylthio, n-propylthio, i-propylthio, t-butylthio, s-butylthio, n-butylthio, i-butylthio, pentylthio, hexylthio, heptylthio, octylthio, nonylthio, decylthio, 3,7-dimethyloctylthio, 2-ethylhexylthio, trifluoromethylthio, 2-cyanoethylthio, benzylthio, 4-chlorobenzylthio, 4-methyl benzylthio, cyclopentylthio and cyclohexylthio.

7. An organic thin film transistor comprising:
an organic semiconductor layer comprising the arylamine of claim 1.

8. The organic thin film transistor according to claim 7, further comprising:
a structure comprising a pair of electrodes configured to apply a current through the organic semiconductor layer; and
a third electrode.

9. The organic thin film transistor according to claim 8, wherein the third electrode and the structure are provided with an insulating layer therebetween.

10. An organic thin film transistor comprising:
an organic semiconductor layer comprising the arylamine of claim 2.

11. The organic thin film transistor according to claim 10, further comprising:
a structure comprising a pair of electrodes configured to apply a current through the organic semiconductor layer; and
a third electrode.

12. The organic thin film transistor according to claim 11, wherein the third electrode and the structure are provided with an insulating layer therebetween.

13. An organic thin film transistor comprising:
an organic semiconductor layer comprising the arylamine of claim 3.

14. The organic thin film transistor according to claim 13, further comprising:
a structure comprising a pair of electrodes configured to apply a current through the organic semiconductor layer; and
a third electrode.

15. The organic thin film transistor according to claim 14, wherein the third electrode and the structure are provided with an insulating layer therebetween.
